(19) United States
(12) Patent Application Publication
(10) Pub. No.: US 2022/0392682 A1
(43) Pub. Date: Dec. 8, 2022

(54) MAGNETIC SHIELD

(71) Applicant: The University of Nottingham, Nottingham (GB)

(72) Inventors: Mark FROMHOLD, Nottingham (GB); Richard BOWTELL, Nottingham (GB); Matthew BROOKES, Nottingham (GB); Michael PACKER, Nottingham (GB); Dominic SIMS, Nottingham (GB); Peter HOBSON, Nottingham (GB)

(21) Appl. No.: 17/753,926

(22) PCT Filed: Sep. 18, 2020
(86) PCT No.: PCT/GB2020/052275

§ 371 Date: Mar. 18, 2022

(30) Foreign Application Priority Data
Sep. 19, 2019 (GB) 1913549.0

(51) Int. Cl. H01F 7/20

(52) U.S. Cl. CPC H01F 7/20

(57) ABSTRACT

A method of designing a magnetic shield comprising a structure enclosing a space, the structure comprising passive magnetic shielding material and a winding configured to produce a specified magnetic within the structure when current is passed through the winding, is disclosed. The method comprises determining an optimised configuration of the winding accounting for the presence of the passive magnetic shield material by implementing one or more boundary conditions at the surface of the passive magnetic shielding material.

### FIELD OF THE INVENTION

The present invention relates to a magnetic shield, and methods for designing a magnetic shield.

### BACKGROUND

Regions of space in which magnetic fields are cancelled so as to produce a substantially magnetic field free environment are required for a variety of different purposes [1], for example laboratory experiments, hospital testing etc. Typically, this is achieved by placing a large amount of high magnetic permeability material (i.e., passive magnetic shielding material) around the region in which magnetic fields are to be cancelled. The amount of high magnetic permeability material can be partially reduced by using an active cancellation system (for example, current carrying coils). However, the presence of high magnetic permeability material warps the magnetic fields produced by the active cancellation coil system.

Optimising active field cancellation (or generation) systems in the presence of passive magnetic shielding material (e.g., high magnetic permeability material) is a long-standing challenge in electromagnetism. It is required for multiple applications, for example biomedical imaging, quantum sensing of gravity, geophysical surveys and underground mapping, and noise suppression in precision measurement. However, optimisation of arbitrary active field-generating coils, or conductor networks, in the presence of passive magnetic shielding material (for example, Mu-metal®) has not yet been implemented.

### SUMMARY

According to a first aspect, there is provided a method of designing a magnetic shield (or magnetic field generating system) comprising a structure enclosing a space, the structure comprising passive magnetic shielding material, and a winding configured to produce a specified magnetic field within the structure when current is passed through the winding. The method may comprise determining an optimised configuration of the winding accounting for the presence of the passive magnetic shielding material by implementing one or more boundary conditions at the surface of the passive magnetic shielding material. The method may be computer-implemented.

Warping of a desired magnetic field to be produced by a winding may be avoided by accounting for the presence of a passive magnetic shielding material in the optimisation process. This may improve accuracy of magnetic field generation and/or magnetic field cancellation in such magnetic shields.

The one or more boundary conditions may require that the magnetic field (for example, one or more vector components of the magnetic field) produced by the winding is zero on a surface of the passive magnetic shielding material.

Accounting for the presence of the passive magnetic shielding material may comprise constructing a function, or discrete approximation thereof, for a geometry of the structure, that can be used to solve differential equations relating magnetic field to current density.

The function may be a Green's function subject to one or more Dirichlet boundary conditions. The method may further comprise implementing the method of mirror images.

Determining an optimised configuration of the winding comprises implementing an optimisation process. The optimisation process may be a least squares minimisation process. The method may comprise regularising the least squares minimisation with a penalty term. The penalty term may be or comprise at least one of a power consumption of the winding, a curvature of the winding configuration, a resistance, an inductance of the winding, a mass and/or volume of the winding, and an energy stored in the winding. The optimisation process may comprise solving one or more sets of simultaneous equations.

Determining an optimised configuration of the winding may comprise determining optimal surface currents on the structure required to produce the specified magnetic field within the structure. The surface currents may be defined by a stream function. Determining the optimal surface currents may comprise determining streamlines of the stream function. Determining streamlines of the stream function may comprise discretising the streamfunction to determine contours of the stream function.

Determining an optimised configuration of the winding may comprise defining at least one discrete winding element having at least one free parameter. Determining an optimised configuration of the winding may further comprise optimising at least one free parameter of each of the discrete winding elements to produce the specified magnetic field within the structure. The free parameters of each of the discrete winding elements may be collectively optimised to produce the specified magnetic field within the structure.

Each of the discrete winding elements may be defined by parametric curves, for example one or more of a straight line, an arc, a circular loop, or any other discrete configuration of wire. The at least one free parameter of each discrete winding element may be or comprise at least one of a size, a shape, a spacing, a placement and an orientation of the discrete winding element.

Determining an optimised configuration of the winding may comprise determining expressions for components of current density for each of the discrete winding elements. The method may further comprise substituting the expressions for components of current density into expressions for components of the magnetic field produced by an arbitrary winding configuration. The method may also comprise implementing an optimisation process to determine, for the specified field, optimal values relating to the components of current density. The optimal values may be or include an optimal free parameter, and/or an optimal relationship between free parameters, of the discrete winding elements. The optimal values may be or include an optimal relationship between radii and separations of the discrete winding elements.

The magnetic field may be one of a constant magnetic field, a linear gradient magnetic field or a higher-order magnetic field.

The structure may be a closed structure. The structure may be a hollow cylinder. The hollow cylinder may comprise an axial body and planar end surfaces. Separate boundary conditions may be implemented for an axial surface of the cylinder and planar end surfaces of the cylinder.

The method may further comprise making a winding corresponding to or approximating the optimised configuration of the winding.

According to a second aspect, there is provided a magnetic shield (or magnetic field generating system) designed using the method of the first aspect.

According to a third aspect, there is provided a magnetic shield (or magnetic field generating system). The magnetic shield may comprise a structure enclosing a space. The structure may comprise passive magnetic shielding material. The magnetic shield may also comprise a winding configured to produce a specified magnetic field within the structure when current is passed through the winding. A configuration of the winding may be optimised such that a field produced by the winding is more similar to the specified magnetic field when the winding is in the presence of the structure than when the winding is not in the presence of the structure.

A magnetic shield in accordance with the third aspect may have improved accuracy of magnetic field generation and/or magnetic field cancellation when compared to existing magnetic shields. A reduction in performance of the winding (for example, an error relative to the specified magnetic field) may be measurable when the winding is operated not in the presence of the structure comprising passive magnetic shielding material.

The structure may be a closed structure. The structure may be a hollow cylinder.

The winding may be disposed within the space enclosed by the structure. The winding may be disposed on an interior surface of the structure.

The winding, in the presence of the structure, may be configured to produce a uniform magnetic field over a volume of at least 1000 cm³ with a relative field variation of less than 1%.

### BRIEF DESCRIPTION OF DRAWINGS

The invention will now be described by way of example with reference to the accompanying drawings in which:

FIG. 1 shows a method for designing a magnetic shield in accordance with the invention;

FIGS. 2A and 2B show other methods for designing a magnetic shield in accordance with the invention, using a Green's function approach;

FIG. 3 shows a conducting open cylindrical shell of length L and radius a about the origin;

FIG. 4 shows a passive magnetic shield cylinder of length \hat{L} and radius b with planar end caps located at z=±\hat{L}/2 enclosing an interior conducting open cylindrical shell of length L₁-L₂ and radius a;

FIGS. 5A to 5D show winding configurations optimised omitting interactions with passive magnetic shielding material;

FIGS. 5E to 5H show field homogeneity of magnetic fields produced by the windings shown in FIGS. 5A to 5D;

FIGS. 6A to 6D show winding configurations optimised accounting for interactions with passive magnetic shielding material in accordance with an embodiment of the invention;

FIGS. 6E and 6F show field homogeneity of magnetic fields produced by the windings shown in FIGS. 6A to 6D;

FIGS. 6G and 6H respectively show a flow of current in various regions of the winding shown in FIG. 6D, and how loops in the winding configuration of FIG. 6D are connected to produce the flow of current in FIG. 6G; and

FIGS. 7A to 7D show optimised winding configurations in accordance with an embodiment of the invention, and associated magnetic field strength distributions

FIG. 8 shows a hollow cylinder of high magnetic permeability of length Lₛ, radius pₛ with planar end caps located at z=±Lₛ/2 enclosing a circular coil of radius ρ_{c}<ρₛ centred along the z-axis and lying in the z=z′ plane;

FIGS. 9A and 9B show planar winding configurations optimised accounting for interactions with passive magnetic shielding material in accordance with an embodiment of the invention;

FIGS. 9C and 9D show magnetic field and magnetic field homogeneity generated by the winding configurations shown in FIGS. 9A and 9B.

Features which are described in the context of separate aspects and embodiments of the invention may be used together and/or be interchangeable wherever possible. Similarly, where features are, for brevity, described in the context of a single embodiment, these may also be provided separately or in any suitable sub-combination. Features described in combination with the system may have corresponding features definable with respect to the method, and these embodiments are specifically envisaged.

### DETAILED DESCRIPTION

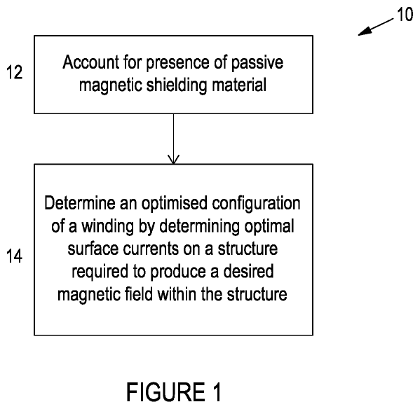

FIG. 1 shows a method 10 for designing a magnetic shield, or other magnetic field-generating structure. The magnetic shield comprises a structure enclosing a space, the structure comprising a passive magnetic shielding material. The magnetic shield also comprises a winding configured to produce a magnetic field to cancel unwanted magnetic fields, or generate specified fields, within the structure when current is passed through the winding. The method 10, at step 12, comprises accounting for the presence of the passive magnetic shielding material. In some embodiments, accounting for the presence of the passive magnetic shielding material comprises implementing one or more boundary conditions relating to physical constraints on the magnetic field produced by the winding due to the passive magnetic shielding material. The one or more boundary conditions may require that one or more components of the magnetic field produced by the winding are zero, or close to zero if the full characteristics of the shielding material are included, on a surface of the passive magnetic shielding material. The method 10, at step 14, also comprises determining an optimised configuration of the winding by determining optimal surface currents on the structure required to produce a desired magnetic field within the structure. The term ‘passive magnetic shielding material’ used herein is intended to include all materials which are magnetisable (i.e., the material can support or alter a magnetic field within itself) in response to an applied magnetic field. It is this property which enables such materials to provide a shielding effect from external magnetic fields. For example, a passive magnetic shielding material may have a relative permeability of substantially 1000 or greater.

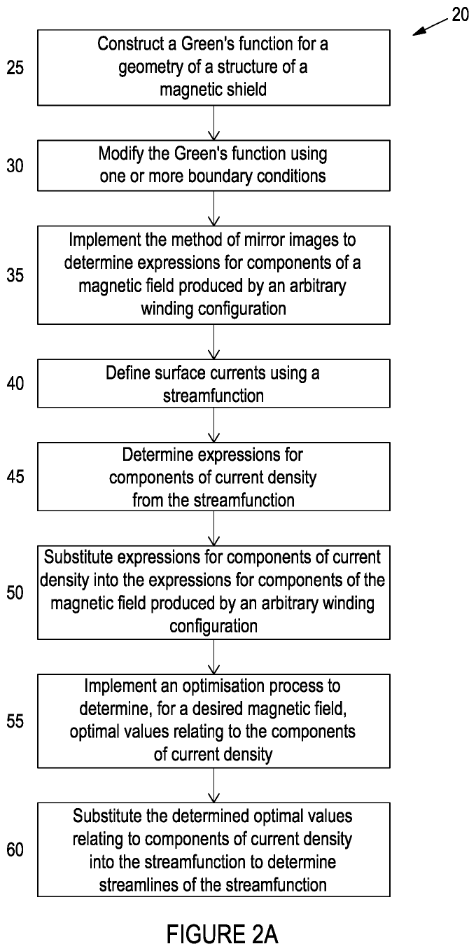

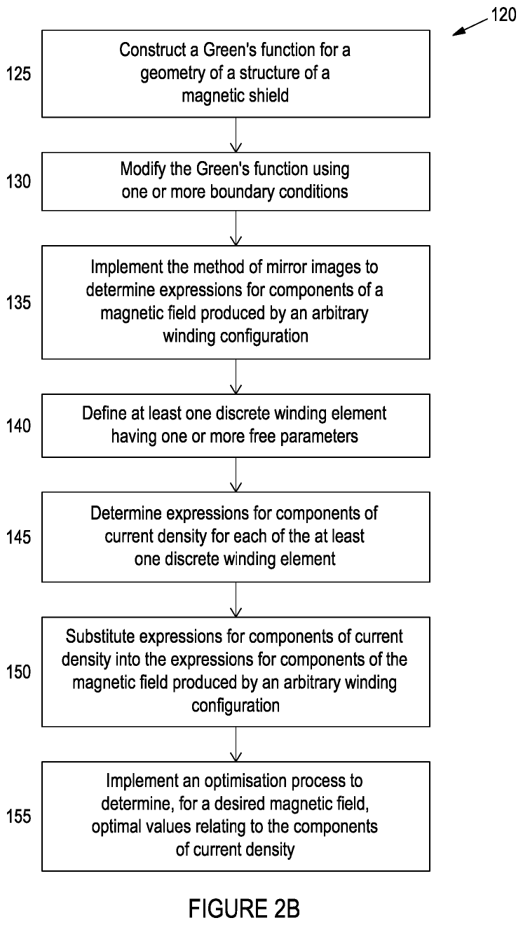

One approach for designing a magnetic shield, or field-generating structure, as described with respect to the method outlined in FIG. 1 (described above) is the method 20 shown in FIG. 2A.

At step 25, the method 20 comprises constructing a function (for example a Green's function), or discrete approximation thereof, for a geometry of the structure of the magnetic shield, that can be used to solve differential equations relating magnetic field and current density.

At step 30, the method 20 comprises modifying the function (for example, the Green's function) using, or subjecting the function to, one or more boundary conditions. The one or more boundary conditions represent physical constraints relating to the magnetic field intended to be produced by the optimised winding configuration. The one or more boundary conditions may be Dirichlet boundary conditions. The one or more boundary conditions may require that one or more components of the magnetic field produced by the winding is zero on a surface of the passive magnetic shielding material.

At step 35, the method 20 comprises implementing the one or more boundary conditions used to modify the function (for example, the Green's function). For example, the method of mirror images may be used to implement the one or more boundary conditions used to modify the Green's function. The method of mirror images may be used to determine expressions for components of the magnetic field produced by an arbitrary winding configuration.

Steps 25 to 35 of the method 20 may account for the presence of the passive magnetic shielding material in determining an optimised configuration of the winding.

At step 40, the method 20 comprises defining surface currents using a streamfunction. The streamfunction represents the fact that current density is restricted to flow over a surface geometry, i.e., that surface currents are used to produce a desired magnetic field. The aim of the optimisation is to determine the streamfunction, and hence, the optimal winding configuration to give a desired magnetic field (for example, a winding configuration that most closely approximates the stream function).

At step 45, the method 20 comprises determining expressions for components of current density from the streamfunction. For example, a Fourier decomposition of the streamfunction may be used to determine expressions for components of current density.

At step 50, the method 20 comprises substituting the expressions for components of current density into the expressions for components of the magnetic field produced by an arbitrary winding configuration.

At step 55, the method 20 comprises implementing an optimisation process to determine, for a desired magnetic field, optimal values relating to the components of current density. The optimisation process may be a least squares minimisation. The least squares minimisation may be regularised using a penalty term. The penalty term may comprise at least one of a power consumption of the winding, a curvature of the winding configuration, an inductance and/or resistance of the winding, and an energy stored in the winding. The optimal values may be optimal Fourier coefficients (the Fourier coefficients introduced by a Fourier decomposition of the streamfunction).

At step 60, the method 20 comprises substituting the determined optimal values relating to components of current density into the stream function to determine streamlines of the stream function (and therefore, optimal surface currents) to produce the desired magnetic field. Determining streamlines of the stream function may comprise discretising the stream function to determine contours of the stream function (for example, such that a winding configuration can be used to approximate the contours of the streamfunction).

Steps 40 to 60 of the method 20 determine an optimised configuration of the winding by determining optimal surface currents on the structure required to produce a desired magnetic field within the structure.

Another approach for designing a magnetic shield, or field-generating structure, as described with respect to the method outlined in FIG. 1 (described above) is the method 120 shown in FIG. 2B. Steps 125 to 135 of the method 120 are substantially identical to the steps 25 to 35 of the method 20 described above. Steps 125 to 135 may account for the presence of the passive magnetic shielding material in determining an optimised configuration of the winding.

At step 140, the method 120 comprises defining or specifying at least one discrete winding element having one or more free parameters. As used herein, the term ‘discrete’ is intended to mean that each of the elements may be considered as a separate and distinct element from each of the other elements (although multiple discrete winding elements may be used to form a complete winding). The discrete winding elements may be defined by parametric curves such as straight lines, arcs or circular loops, or by any other discrete configuration of wire, to form a winding. The one or more free parameters may be or include at least one of a form (for example, a size and/or a shape) a spacing, a placement and an orientation of the discrete winding elements to determine an optimal winding configuration to produce a desired magnetic field. Spacing refers to the distance between associated discrete elements (for example, the distance between a pair of coils in either a symmetric or asymmetric arrangement, depending on the desired harmonic field) of the winding. Placement refers to the location of associated discrete elements (for example, a pair of coils in either a symmetric or asymmetric arrangement) relative to other discrete elements of the winding. The free parameters of the discrete elements may be collectively optimised to generate a desired magnetic field.

At step 145, the method 120 comprises determining expressions for components of current density for each of the at least one discrete winding elements. The expressions may relate components of current density to the one or more free parameters of each of the discrete winding elements.

At step 150, the method 120 comprises substituting the expressions for components of current density into expressions for components of a magnetic field produced by an arbitrary winding configuration.

At step 155, the method 120 comprises implementing an optimisation process to determine, for a desired magnetic field, one or more optimal values relating to the components of current density. The optimisation process may be implemented by solving simultaneous equations. The one or more optimal values may be or include an optimal free parameter, or an optimal relationship between free parameters of the discrete winding elements (for example, a ratio between radii and axial separation of circular loops).

Steps 140 to 155 of the method 120 determine an optimised configuration of the winding by optimising one or more free parameters of the discrete winding elements to produce a desired magnetic field within the structure.

In the embodiment discussed below, a winding configuration is optimised for a magnetic shield, or other magnetic field-generating system, comprising a closed cylinder of passive magnetic shielding material and a winding disposed in the interior of the closed cylinder. Boundary conditions ensure that the value of the magnetic field generated by the winding attain the correct physical limit at the boundaries of the closed cylinder.

The magnetic vector potential satisfies Poisson's non-homogeneous equation,

∇²A(r)=−μ₀J(r′) (1.1)

where J(r′) is the current density. As presented in various papers and textbooks [2], the solution to this PDE is given in integral notation by

A(r)=μ₀∫_{r′}dr′G(r,r′)J(r′) (1.2)

where, in general, a Green's function with Dirichlet boundary conditions satisfies

∇²G(r,r′)=−δ(r−r′) (1.3)

Consider the case of the Green's function in cylindrical coordinates without passive magnetic shielding material. Since the Laplacian in cylindrical coordinates is separable, it is possible to construct a Green's function of the form

G(r,r′)=R(ρ,ρ′)Φ(ϕ,ϕ′)Z(z,z′) (1.4)

The Laplacian operator in cylindrical coordinates is given by

$${∇}^{2} G = \frac{1}{ρ} \frac{\partial }{\partial ρ} ( ρ \frac{\partial G}{\partial ρ} ) + \frac{1}{{ρ}^{2}} \frac{{\partial }^{2} G}{\partial {ϕ}^{2}} + \frac{{\partial }^{2} G}{\partial {z}^{2}} \qquad ( 1.5 )$$

Inserting 1.4 into 1.5, it is found

$$\frac{1}{ρ} \frac{{R}^{′}}{R} + \frac{{R}^{″}}{R} + \frac{1}{{ρ}^{2}} \frac{{Φ}^{″}}{Φ} + \frac{{Z}^{″}}{Z} = 0 , ρ \neq 0 \qquad ( 1.6 )$$

The separation constants associated with Z may be chosen to be either ±k². Here, −k² is chosen in order to more easily apply boundary conditions when calculating the Green's function in the presence of passive magnetic shielding material. Separating 1.6, it is found that

Z″+k²Z=0 (1.7)

Φ″+m²Φ=0 (1.8)

Substituting 1.7 and 1.8 into 1.6, it is found that

ρ²R″+ρR′−(k²ρ+m²)R=0 (1.9)

This results in 1.9 having the general solution

$${R}_{m} ( ρ , {ρ}^{′} , k ) = \{ \begin{matrix}{A}_{m} ( {ρ}^{′} , k ) {I}_{m} ( k ρ ) + {B}_{m} ( {ρ}^{′} , k ) {K}_{m} ( k ρ ) & 0 < ρ < {ρ}^{′} < ∞ \\ {C}_{m} ( {ρ}^{′} , k ) {I}_{m} ( k ρ ) + {D}_{m} ( {ρ}^{′} , k ) {K}_{m} ( k ρ ) & 0 < {ρ}^{′} < ρ < ∞\end{matrix} \qquad ( 1.1 )$$

where Iᵥ(z) and Kᵥ(z) are the modified Bessel functions of the first and second kind, respectively. In cylindrical coordinates we may write

$$\begin{matrix}δ ( r - {r}^{′} ) = \frac{1}{ρ} δ ( ρ - {ρ}^{′} ) δ ( ϕ - {ϕ}^{′} ) δ ( z - {z}^{′} ) \\ = \frac{1}{ρ} δ ( ρ - {ρ}^{′} ) \frac{1}{4 {π}^{2}} {\sum }_{m = - ∞}^{∞} {e}^{im ( ϕ - {ϕ}^{′} )} {\int }_{- ∞}^{∞} {dke}^{ik ( z - {z}^{′} )}\end{matrix} \qquad ( 1.11 )$$

using the Cauchy principle value, and satisfying the requirements for the azimuthal dependence to be single valued quantised and unbounded in z. In order to avoid future problems with negative values of k, 1.11 may be rewritten as

$$δ ( r - {r}^{′} ) = \frac{1}{ρ} δ ( ρ - {ρ}^{′} ) \frac{1}{2 {π}^{2}} {\sum }_{m = - ∞}^{∞} {e}^{im ( ϕ - {ϕ}^{′} )} {\int }_{0}^{∞} dk cos ( k ( z - {z}^{′} ) ) \qquad ( 1.12 )$$

As for the ρ dependence, it is required that G be finite at ρ,ρ′=0 and zero at ρ,ρ′=∞ for ρ′>ρ and ρ>ρ′ respectively. From these conditions, the coefficients Bₘ(ρ′,k)=0 and Cₘ(ρ′,k)=0 giving

$${R}_{m} ( ρ , {ρ}^{′} , k ) = \{ \begin{matrix}{A}_{m} ( {ρ}^{′} , k ) {I}_{m} ( k ρ ) & 0 < ρ < {ρ}^{′} < ∞ \\ {D}_{m} ( {ρ}^{′} , k ) {K}_{m} ( k ρ ) & 0 < {ρ}^{′} < ρ < ∞\end{matrix} \qquad ( 1.13 )$$

Writing the continuity theorem we have

Rₘ(ρ,ρ′,k)|_{ρ=ρ′}_{⁺}=Rₘ(ρ,ρ′,k)|_{ρ=ρ′}_{^{−}} (1.14)

giving

$${R}_{m} ( ρ , {ρ}^{′} , k ) = \{ \begin{matrix}{AI}_{m} ( k ρ ) {K}_{m} ( k {ρ}^{′} ) & 0 < ρ < {ρ}^{′} < ∞ \\ {AI}_{m} ( k {ρ}^{′} ) {K}_{m} ( k ρ ) & 0 < {ρ}^{′} < ρ < ∞\end{matrix} \qquad ( 1.15 )$$

The Green's function may now be written as

$$G ( r , {r}^{′} ) = \frac{A}{2 {π}^{2}} {\sum }_{m = - ∞}^{∞} {e}^{im ( ϕ - {ϕ}^{′} )} {\int }_{0}^{∞} dk cos ( k ( z - {z}^{′} ) ) {I}_{m} ( k {ρ}_{<} ) {K}_{m} ( k {ρ}_{>} ) \qquad ( 1.16 )$$

where ρ_{>} is the larger of ρ and ρ′ and ρ_{<} is the smaller of the two quantities. Substituting G into 1.5 and integrating over the infinitesimal interval (ρ′⁻, ρ′⁺) yields

$${{{\int }_{ρ = {ρ}^{′ -}}^{ρ = {ρ}^{′ +}} d ρ \frac{{\partial }^{2} G}{\partial {z}^{2}} + \frac{1}{{ρ}^{2}} \frac{{\partial }^{2} G}{\partial {ϕ}^{2}} + \frac{1}{ρ} \frac{\partial G}{\partial ρ} + \frac{{\partial }^{2} G}{\partial {ρ}^{2}} = \frac{\partial G}{\partial ρ} \vert}_{ρ = {ρ}^{′ +}} - \frac{\partial G}{\partial ρ} \vert}_{ρ = {ρ}^{′ -}} \qquad ( 1.17 )$$

which satisfies 1.3, giving

$$\frac{A}{2 {π}^{2}} {\sum }_{m = - ∞}^{∞} {e}^{im ( ϕ - {ϕ}^{′} )} {\int }_{0}^{∞} dk cos ( k ( z - {z}^{′} ) ) ( {I}_{m} ( k {ρ}^{′} ) {K}_{m}^{′} ( k {ρ}^{′} ) - {I}_{m}^{′} ( k {ρ}^{′} ) {K}_{m} ( k {ρ}^{′} ) ) = - {\int }_{ρ = {ρ}^{′ -}}^{ρ = {ρ}^{′ +}} d ρ \frac{- δ ( ρ - {ρ}^{′} ) δ ( ϕ - {ϕ}^{′} ) δ ( z - {z}^{′} )}{ρ} \qquad ( 1.18 )$$

Using the identity

$${I}_{v} ( z ) {K}_{v}^{′} ( z ) - {I}_{v}^{′} ( z ) {K}_{v} ( z ) = - \frac{1}{2} \qquad ( 1.19 )$$

where I′ₘ(z) and K′ₘ(z) are the derivatives of Iₘ(z) and Kₘ(z) with respect to z respectively, it then follows from 1.18 that A=1, resulting in the Green's function

$$G ( r , {r}^{′} ) = \frac{1}{2 {π}^{2}} {\sum }_{m = - ∞}^{∞} {e}^{im ( ϕ - {ϕ}^{′} )} {\int }_{0}^{∞} dk cos ( k ( z - {z}^{′} ) ) {I}_{m} ( {kp}_{<} ) {K}_{m} ( k {ρ}_{>} ) \qquad ( 1.2 )$$

which may be finally rewritten as

$$G ( r , {r}^{′} ) = \frac{1}{4 {π}^{2}} {\sum }_{m = - ∞}^{∞} {e}^{im ( ϕ - {ϕ}^{′} )} {\int }_{- ∞}^{∞} {dke}^{ik ( z - {z}^{′} )} {I}_{m} ( \vert k \vert {ρ}_{<} ) {K}_{m} ( \vert k \vert {ρ}_{>} ) \qquad ( 1.21 )$$

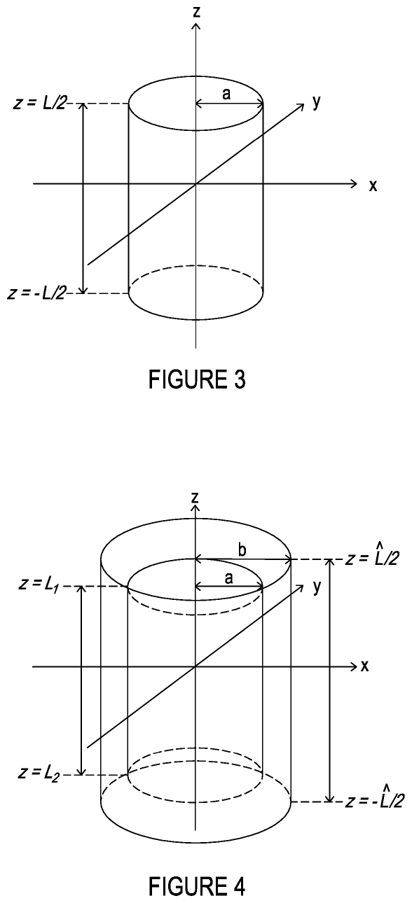

Now, generating optimal surface coils, on a finite open cylinder of length L and radius a about the origin (as shown in FIG. 3), in order to generate an arbitrary specified magnetic field in the interior of the cylinder is considered. The vector potential takes the form of 1.2, where

r=ρ cos ϕi+ρ sin ϕj+zk (1.22 )

r′=a cos ϕ′i+a sin ϕ′j+z′k (1.23)

Following the formulation of R. Turner and R. M. Bowley [3], the three components in cylindrical coordinates may be written as

A_{ρ}(r)=μ₀∫_{r′}dr′G(r,r′)J_{ϕ}(r′)sin(ϕ−ϕ′) (1.24)

A_{ϕ}(r)=μ₀∫_{r′}dr′G(r,r′)J_{ϕ}(r′)cos(ϕ−ϕ′) (1.25)

A_{z}(r)=μ₀∫_{r′}dr′G(r,r′)J_{z}(r′) (1.26)

Through the substitution of 1.21 into 1.24, 1.25 and 1.26 the components of A on the interior of the cylinder are

$${A}_{ρ} ( ρ , ϕ , z ) = - \frac{i {μ}_{0} a}{8 {π}^{2}} {\sum }_{m = - ∞}^{∞} {\int }_{- ∞}^{∞} {dke}^{im ϕ} {e}^{ikz} [ {I}_{m - 1} ( \vert k \vert ρ ) {K}_{m - 1} ( \vert k \vert a ) - \\ {I}_{m + 1} ( \vert k \vert ρ ) {K}_{m + 1} ( \vert k \vert a ) ] {\int }_{0}^{2 π} d {ϕ}^{′} {e}^{- im {ϕ}^{′}} {\int }_{- ∞}^{∞} {dz}^{′} {e}^{- {ikz}^{′}} {J}_{ϕ} ( {ϕ}^{′} , {z}^{′} ) \qquad ( 1.27 )$$

$${A}_{ϕ} ( ρ , ϕ , z ) = \frac{{μ}_{0} a}{8 {π}^{2}} {\sum }_{m = - ∞}^{∞} {\int }_{- ∞}^{∞} {dke}^{im ϕ} {e}^{ikz} [ {I}_{m - 1} ( \vert k \vert ρ ) {K}_{m - 1} ( \vert k \vert a ) + \\ {I}_{m + 1} ( \vert k \vert ρ ) {K}_{m + 1} ( \vert k \vert a ) ] {\int }_{0}^{2 π} d {ϕ}^{′} {e}^{- im {ϕ}^{′}} {\int }_{- ∞}^{∞} {dz}^{′} {e}^{- {kz}^{′}} {J}_{ϕ} ( {ϕ}^{′} , {z}^{′} ) \qquad ( 1.28 )$$

$${A}_{z} ( ρ , ϕ , z ) = \frac{{μ}_{0} a}{4 {π}^{2}} {\sum }_{m = - ∞}^{∞} {\int }_{- ∞}^{∞} {dke}^{im ϕ} {e}^{ikz} {I}_{m} ( \vert k \vert ρ ) {K}_{m} ( \vert k \vert a ) \times \\ {\int }_{0}^{2 π} d {ϕ}^{′} {e}^{- im {ϕ}^{′}} {\int }_{- ∞}^{∞} {dz}^{′} {e}^{- {ikz}^{′}} {J}_{z} ( {ϕ}^{′} , {z}^{′} ) \qquad ( 1.29 )$$

At this point it becomes useful to define the Fourier transforms of the current densities,

$${J}_{ϕ}^{m} ( k ) = \frac{1}{2 π} {\int }_{0}^{2 π} d {ϕ}^{′} {e}^{- im {ϕ}^{′}} {\int }_{- ∞}^{∞} {dz}^{′} {e}^{- {ikz}^{′}} {J}_{ϕ} ( {ϕ}^{′} , {z}^{′} ) \qquad ( 1.3 )$$

$${J}_{z}^{m} ( k ) = \frac{1}{2 π} {\int }_{0}^{2 π} d {ϕ}^{′} {e}^{- im {ϕ}^{′}} {\int }_{- ∞}^{∞} {dz}^{′} {e}^{- {ikz}^{′}} {J}_{z} ( {ϕ}^{′} , {z}^{′} ) \qquad ( 1.31 )$$

such that their inverse transforms are given by

$${J}_{ϕ} ( {ϕ}^{′} , {z}^{′} ) = \frac{1}{2 π} {\sum }_{m = - ∞}^{∞} {\int }_{- ∞}^{∞} {dke}^{im {ϕ}^{′}} {e}^{{ikz}^{′}} {J}_{ϕ}^{m} ( k ) \qquad ( 1.32 )$$

$${J}_{Z} ( {ϕ}^{′} , {z}^{′} ) = \frac{1}{2 π} {\sum }_{m = - ∞}^{∞} {\int }_{- ∞}^{∞} {dke}^{im {ϕ}^{′}} {e}^{{ikz}^{′}} {J}_{Z}^{m} ( k ) \qquad ( 1.33 )$$

For future simplification a relation between J_{z}^{m}(k) and J_{ϕ}^{m}(k) will prove useful. As such, using the continuity equation, restricting the current to flow only on the surface of a cylinder of radius a, gives

$$\frac{1}{a} \frac{\partial {J}_{ϕ} ( {ϕ}^{′} , {z}^{′} )}{\partial {ϕ}^{′}} + \frac{\partial {J}_{z} ( {ϕ}^{′} , {z}^{′} )}{\partial {ϕ}^{′}} = 0 , on ρ = a \qquad ( 1.34 )$$

Substituting 1.32 and 1.33 into 1.34 results in

$$\frac{i}{2 π} {\sum }_{m = - ∞}^{∞} {\int }_{- ∞}^{∞} dk ( \frac{m}{a} {J}_{ϕ}^{m} ( k ) + {kJ}_{z}^{m} ( k ) ) {e}^{im {ϕ}^{′}} {e}^{{ikz}^{′}} = 0 \qquad ( 1.35 )$$

yielding the relationship between J_{z}^{m}(k) and J_{ϕ}^{m}(k) to be given by

$${J}_{z}^{m} ( k ) = - \frac{m}{ka} {J}_{ϕ}^{m} ( k ) \qquad ( 1.36 )$$

Through the use of 1.30 and 1.31, 1.27, 1.28 and 1.29 are simplified to

$${A}_{ρ} ( ρ , ϕ , z ) = - \frac{i {μ}_{0} a}{4 π} {\sum }_{m = - ∞}^{∞} {\int }_{- ∞}^{∞} {dke}^{im ϕ} {e}^{ikz} [ {I}_{m - 1} ( \vert k \vert ρ ) {K}_{m - 1} ( \vert k \vert a ) - \\ {I}_{m + 1} ( \vert k \vert ρ ) {K}_{m + 1} ( \vert k \vert a ) ] {J}_{ϕ}^{m} ( k ) \qquad ( 1.37 )$$

$${A}_{ϕ} ( ρ , ϕ , z ) = \frac{{μ}_{0} a}{4 π} {\sum }_{m = - ∞}^{∞} {\int }_{- ∞}^{∞} {dke}^{im ϕ} {e}^{ikz} [ {I}_{m - 1} ( \vert k \vert ρ ) {K}_{m - 1} ( \vert k \vert a ) - \\ {I}_{m + 1} ( \vert k \vert ρ ) {K}_{m + 1} ( \vert k \vert a ) ] {J}_{ϕ}^{m} ( k ) \qquad ( 1.38 )$$

$${A}_{z} ( ρ , ϕ , z ) = \frac{{μ}_{0} a}{2 π} {\sum }_{m = - ∞}^{∞} {\int }_{- ∞}^{∞} {dke}^{im ϕ} {e}^{ikz} {I}_{m} ( \vert k \vert ρ ) {K}_{m} ( \vert k \vert a ) {J}_{z}^{m} ( k ) \qquad ( 1.39 )$$

From this the magnetic field generated by an arbitrary coil on the surface of a cylinder may be calculated, taking the curl of A,

$$B = ▽ ∧ A = ( \frac{1}{ρ} \frac{\partial {A}_{z}}{\partial ϕ} - \frac{\partial {A}_{ϕ}}{\partial z} ) \hat{ρ} + ( \frac{\partial {A}_{ρ}}{\partial z} - \frac{\partial {A}_{z}}{\partial ρ} ) \hat{ϕ} + \frac{1}{ρ} ( \frac{\partial }{\partial ρ} ( ρ {A}_{ϕ} ) - \frac{\partial {A}_{ρ}}{\partial ϕ} ) \hat{z} \qquad ( 1.4 )$$

while using 1.36 and the recurrence relations for the modified Bessel functions

$${I}_{m \pm 1} ( z ) = {I}_{m}^{′} ( z ) ∓ \frac{m}{z} {I}_{m} ( z ) \qquad ( 1.41 )$$

$${K}_{m \pm 1} ( z ) = - {K}_{m}^{′} ( z ) \pm \frac{m}{z} {K}_{m} ( z ) \qquad ( 1.42 )$$

where I′ₘ(z) and K′ₘ(z) are the derivatives of Iₘ(z) and Kₘ(z) with respect to z respectively, the magnetic field B components of the interior of the cylinder are given by

$${B}_{ρ} ( ρ , ϕ , z ) = \frac{i {μ}_{0} a}{2 π} {\sum }_{m = - ∞}^{∞} {\int }_{- ∞}^{∞} dk {ke}^{im ϕ} {e}^{ikz} {I}_{m}^{′} ( \vert k \vert ρ ) {K}_{m}^{′} ( \vert k \vert a ) {J}_{ϕ}^{m} ( k ) \qquad ( 1.43 )$$

$${B}_{ϕ} ( ρ , ϕ , z ) = \frac{{μ}_{0} {a}^{2}}{2 π ρ} {\sum }_{m = - ∞}^{∞} {\int }_{- ∞}^{∞} dk \vert k \vert {e}^{im ϕ} {e}^{ikz} {I}_{m} ( \vert k \vert ρ ) {K}_{m}^{′} ( \vert k \vert a ) {J}_{z}^{m} ( k ) \qquad ( 1.44 )$$

$${B}_{z} ( ρ , ϕ , z ) = - \frac{{μ}_{0} a}{2 π} {\sum }_{m = - ∞}^{∞} {\int }_{- ∞}^{∞} dk \vert k \vert {e}^{im ϕ} {e}^{ikz} {I}_{m} ( \vert k \vert ρ ) {K}_{m}^{′} ( \vert k \vert a ) {J}_{ϕ}^{m} ( k ) \qquad ( 1.45 )$$

in agreement with Turner [4]. As with the target field method [4], the current density required to generate a specified target field can now be explicitly calculated. However, since no explicit length of coil is specified in the target field method, the result is slightly unrealistically sized coils. Instead, a Fourier series decomposition of the current density may be employed. Since the current density has been restricted to flow over a surface geometry, through the use of the continuity equation 1.34, the current density may be defined by a single function—the streamfunction, ψ(ϕ′,z). It then follows that

$${J}_{ϕ} ( {ϕ}^{′} , {z}^{′} ) = \frac{\partial ψ ( {ϕ}^{′} , {z}^{′} )}{\partial {z}^{′}} , {J}_{z} ( {ϕ}^{′} , {z}^{′} ) = - \frac{1}{a} \frac{\partial ψ ( {ϕ}^{′} , {z}^{′} )}{\partial {ϕ}^{′}} on ρ = a \qquad ( 1.46 )$$

The set of values ψ(ϕ′,z)=constant denote the streamlines of the surface coil, which will be the subject of the optimisation, thereby yielding the winding pattern of the surface coil that approximates the streamfunction. The aim of the optimisation is to determine the streamfunction and, therefore, the optimal coil geometry to give a desired magnetic field. Consequently, a Fourier decomposition of the streamfunction is given by

$$φ ( {ϕ}^{′} , {z}^{′} ) = H ( {z}^{′} + L / 2 ) - \\ H ( {z}^{′} - L / 2 ) ) [ - {\sum }_{n = 1}^{N} \frac{L}{n π} {P}_{n 0} cos ( \frac{n π ( {z}^{′} + L / 2 )}{L} ) + {\sum }_{n = 1}^{N} {\sum }_{m = 1}^{M} \frac{L}{n π} ( {P}_{n m} cos ( m {ϕ}^{′} ) + {Q}_{n m} sin ( m {ϕ}^{′} ) ) sin ( \frac{n π ( {z}^{′} + L / 2}{L} ) ] \qquad ( 1.47 )$$

where H(x) is the Heaviside step function, resulting in an axial current density,

$${J}_{z} ( {ϕ}^{′} , {z}^{′} ) = ( H ( {z}^{′} + L / 2 ) - H ( {z}^{′} - L / 2 ) ) \{ {\sum }_{n = 1}^{N} {\sum }_{m = 1}^{M} \frac{mL}{n π a} [ {P}_{n m} sin ( m {ϕ}^{′} ) - {Q}_{n m} cos ( m {ϕ}^{′} ) ] sin ( \frac{n π ( z + L / 2}{L} ) \} \qquad ( 1.48 )$$

which has zero value at z=±L/2. The azimuthal component of the current density is given by

$${J}_{ϕ} ( {ϕ}^{′} , {z}^{′} ) = ( H ( {z}^{′} + L / 2 ) - H ( {z}^{′} - L / 2 ) ) [ {\sum }_{n = 1}^{N} {P}_{n 0} sin ( \frac{n π ( {z}^{′} + L / 2}{L} ) + {\sum }_{n = 1}^{N} {\sum }_{m = 1}^{M} ( {P}_{n m} cos ( m {ϕ}^{′} ) + {Q}_{n m} sin ( m {ϕ}^{′} ) ) cos ( \frac{n π ( {z}^{′} + L / 2}{L} ) ] \qquad ( 1.49 )$$

Upon substitution of 1.49 and 1.48 into 1.43, 1.45 and 1.44 respectively, and performing the integration over the surface of the coil, it is found that

$${B}_{ρ} ( ρ , ϕ , z ) = {\sum }_{n = 1}^{N} {P}_{n 0} {F}_{n} ( ρ , z ) + {\sum }_{n = 1}^{N} {\sum }_{m = 1}^{M} ( {P}_{n m} {G}_{n m}^{p} ( ρ , z ) + {Q}_{n m} {G}_{n m}^{q} ( ρ , z ) ) \qquad ( 1.5 )$$

$${B}_{ϕ} ( ρ , ϕ , z ) = {\sum }_{n = 1}^{N} {\sum }_{m = 1}^{M} \frac{mL}{n π ρ} ( {P}_{n m} {H}_{n m}^{p} ( ρ , z ) + {Q}_{n m} {H}_{n m}^{q} ( ρ , z ) ) \qquad ( 1.51 )$$

$${B}_{z} ( ρ , ϕ , z ) = {\sum }_{n = 1}^{N} {P}_{n 0} {H}_{n 0} ( ρ , z ) + {\sum }_{n = 1}^{N} {\sum }_{m = 1}^{M} ( {P}_{n m} {S}_{n m}^{p} ( ρ , z ) + {Q}_{n m} {S}_{n m}^{q} ( ρ , z ) ) \qquad ( 1.52 )$$

in which 1.50, 1.51 and 1.52 contain the predefined functions,

$${F}_{n} ( ρ , z ) = \frac{{μ}_{0} a}{π} {\int }_{0}^{∞} d k k {I}_{0}^{′} ( k ρ ) {K}_{0}^{′} ( k a ) \frac{2 L n π}{{k}^{2} {L}^{2} - {n}^{2} {π}^{2}} ( \begin{matrix}sin ( \frac{k L}{2} ) cos ( k z ) \\ cos ( \frac{k L}{2} ) sin ( k z )\end{matrix} ) \qquad ( 1.53 )$$

$${G}_{n m} ( ρ , z ) = \frac{{μ}_{0} a}{π} {\int }_{0}^{∞} d k k {I}_{m}^{′} ( k ρ ) {K}_{m}^{′} ( k a ) \frac{2 k {L}^{2}}{{k}^{2} {L}^{2} - {n}^{2} {π}^{2}} ( \begin{matrix}- sin ( \frac{k L}{2} ) sin ( k z ) \\ cos ( \frac{k L}{2} ) cos ( k z )\end{matrix} ) \qquad ( 1.54 )$$

$${G}_{n m}^{p} ( ρ , z ) = cos ( m ϕ ) {G}_{n m} ( ρ , z ) , {G}_{n m}^{q} ( ρ , z ) = sin ( m ϕ ) {G}_{n m} ( ρ , z ) \qquad ( 1.55 )$$

$${H}_{n m} ( ρ , z ) = \frac{{μ}_{0} a}{π} {\int }_{0}^{∞} d k k {I}_{m} ( k ρ ) {K}_{m}^{′} ( k a ) \frac{2 L n π}{{k}^{2} {L}^{2} - {n}^{2} {π}^{2}} ( \begin{matrix}- sin ( \frac{k L}{2} ) sin ( k z ) \\ cos ( \frac{k L}{2} ) cos ( k z )\end{matrix} ) \qquad ( 1.56 )$$

$${H}_{n m}^{p} ( ρ , z ) = sin ( m ϕ ) {H}_{n m} ( ρ , z ) , {H}_{n m}^{q} ( ρ , z ) = - cos ( m ϕ ) {H}_{n m} ( ρ , z ) \qquad ( 1.57 )$$

$${S}_{n m} ( ρ , z ) = - \frac{{μ}_{0} a}{π} {\int }_{0}^{∞} d k k {I}_{m} ( k ρ ) {K}_{m}^{′} ( k a ) \frac{2 k {L}^{2}}{{k}^{2} {L}^{2} - {n}^{2} {π}^{2}} ( \begin{matrix}sin ( \frac{k L}{2} ) cos ( k z ) \\ cos ( \frac{k L}{2} ) sin ( k z )\end{matrix} ) \qquad ( 1.58 )$$

$${S}_{n m}^{p} ( ρ , z ) = cos ( m ϕ ) {S}_{n m} ( ρ , z ) , {S}_{n m}^{q} ( ρ , z ) = sin ( m ϕ ) {S}_{n m} ( ρ , z ) \qquad ( 1.59 )$$

where the function in each right-most bracket corresponds to the upper line if n is even and to the lower line if n is odd. From this, the magnetic field generated by an arbitrary coil on the surface of an open cylinder may be calculated in Cartesian coordinates,

Bₓ(ρ,ϕ,z)=cos ϕB_{ρ}(ρ,ϕ,z)−sin ϕB_{ϕ}(ρ,ϕ,z) (1.60)

B_{y}(ρ,ϕ,z)=sin ϕB_{ρ}(ρ,ϕ,z)+cos ϕB_{ϕ}(ρ,ϕ,z) (1.61)

Using the system of governing equations 1.50 to 1.52, solving for the unknown coefficients (Pₙ₀,Pₙₘ,Qₙₘ) is a very ill-conditioned problem due to the formulation of the vector potential in integral representation of 1.24 to 1.26. A least squares minimisation may be used, as shown in the example below, although other optimisation techniques may be employed instead. In some embodiments, a penalty term may be implemented in the optimisation to regularise the problem. The regularisation term may take many forms. For example, individual terms in the regularisation term may represent the curvature of a given coil geometry, or the energy stored in the coil. In the example described below, the penalty term relates to the overall power of the coil. However, the choice of the penalty term is somewhat arbitrary as all regularisation parameters act to achieve the same general goal. If the regularisation term is large, the result is a well-conditioned inverse problem with a more simplistic design compromising field fidelity. On the other hand, if the regularisation term is small, the result is a less well-conditioned inverse problem with a more intricate design prioritising higher field fidelity.

The power dissipation in a surface coil of thickness, t, and resistivity, [symbol] , is given by

$$P = {\int }_{- L / 2}^{L / 2} d {z}^{′} {\int }_{0}^{2 π} d {ϕ}^{′} {\vert {J}_{z} ( {ϕ}^{′} , {z}^{′} ) \vert}^{2} + {\vert {J}_{ϕ} ( {ϕ}^{′} , {z}^{′} \vert}^{2} \qquad ( 1.62 )$$

which, when integrated over the surface of the coil, gives

$$P = [ {\sum }_{n = 1}^{N} {P}_{n 0}^{2} π L + {\sum }_{n = 1}^{N} {\sum }_{m = 1}^{M} ( {P}_{n m}^{2} + {Q}_{n m}^{2} ) ( \frac{π L}{2} + \frac{{m}^{2} {L}^{3}}{2 π {n}^{2} {a}^{2}} ) ] \qquad ( 1.63 )$$

The least squares optimisation may now be represented by the cost function

Φ=αΣₖ[B^{desired}(rₖ)−B(rₖ)]²+βP (1.64)

where α and β are weighting parameters chosen such that the physical parameters may be adjusted to fit physical constraints, with K target field points. The minimisation is achieved by taking the differential of the functional with respect to the Fourier coefficients,

$$\begin{matrix}\frac{\partial Φ}{\partial {P}_{i 0}} = 0 , & \frac{\partial Φ}{\partial {P}_{i j}} = 0 , & \frac{\partial Φ}{\partial {Q}_{i j}} = 0 , & i , j > 1\end{matrix} \qquad ( 1.65 )$$

allowing the optimal Fourier coefficients to be found for any given physical magnetic field through a matrix inversion. The inversion process ends with the solution of the optimal continuous value of the streamfunction defined on the surface of the specified surface. The final objective, however, is to design a coil which generates the desired magnetic field to a specified accuracy. In some embodiments, therefore, an approximate solution to the current continuum is found by discretising the streamfunction, contouring, therefore finding the streamlines. Every position (x,y,z,φ) may be seen as a hyperplane in 4-dimensional space in which the streamlines exist as the set of hypersurfaces in space (x,y,z,φᵢ), which may be projected as a line segment on a 2-dimensional surface, such that

$$Δ φ = \frac{max φ - min φ}{{N}_{c} - 1} , where {φ}_{i} = min φ + i Δ φ \qquad ( 1.66 )$$

with N_{c} being the number of contours.

Now, consider a hollow cylinder of radius b and length L, of infinite permeability, infinitesimal thickness and planar end caps located at z=±\hat{L}/2. An arbitrary current flows over an inner open cylinder of radius a<b and length L<\hat{L} centred about the origin, as shown in FIG. 4. A Green's function needs to be constructed subject to the physical constraints relating to the magnetic field. Physically, the high permeability material changes the magnetisation of the sub-domains in the interior of the passive magnetic shielding material in order to satisfy the condition that

\hat{n}∧H=0 on S (1.67)

which is satisfied provided

B(r)_{∥}=0 on S (1.68)

This condition requires that

B_{ρ}|_{z=±L/2}=0, B_{z}|_{ρ=b}=0, B_{ϕ}|_{z=±L/2,ρ=b}=0 (1.69)

The induced magnetisation sub-domains of the passive shield may be cast into an equivalent pseudo-current density, which is mathematically equivalent. For clarity, perpendicular surfaces will be dealt with separately. The effect from the cylindrical walls of the passive magnetic shield on the vector potential, A, in the region a<ρ<b, results in 1.37, 1.38 and 1.39 being modified such that

$${A}_{ρ} ( ρ , ϕ , z ) = - \frac{i {μ}_{0}}{4 π} {\sum }_{m = - ∞}^{∞} {\int }_{- ∞}^{∞} d k {e}^{i m ϕ} {e}^{i k z} \{ a [ {I}_{m - 1} ( \vert k \vert a ) {K}_{m - 1} ( \vert k \vert ρ ) - {I}_{m + 1} ( \vert k \vert a ) {K}_{m + 1} ( \vert k \vert ρ ) ] {J}_{ϕ}^{m} ( k ) + b [ {I}_{m - 1} ( \vert k \vert ρ ) {K}_{m - 1} ( \vert k \vert b ) - {I}_{m + 1} ( \vert k \vert ρ ) {K}_{m + 1} ( \vert k \vert b ) ( k ) \} \qquad ( 1.7 )$$

$${A}_{ϕ} ( ρ , ϕ , z ) = \frac{{μ}_{0}}{4 π} {\sum }_{m = - ∞}^{∞} {\int }_{- ∞}^{∞} d k {e}^{i m ϕ} {e}^{i k z} \{ a [ {I}_{m - 1} ( \vert k \vert a ) {K}_{m - 1} ( \vert k \vert ρ ) + {I}_{m + 1} ( \vert k \vert a ) {K}_{m + 1} ( \vert k \vert ρ ) ] {J}_{ϕ}^{m} ( k ) + b [ {I}_{m - 1} ( \vert k \vert ρ ) {K}_{m - 1} ( \vert k \vert b ) + {I}_{m + 1} ( \vert k \vert ρ ) {K}_{m + 1} ( \vert k \vert b ) ( k ) \} \qquad ( 1.71 )$$

$${A}_{z} ( ρ , ϕ , z ) = \frac{{μ}_{0}}{2 π} {\sum }_{m = - ∞}^{∞} {\int }_{- ∞}^{∞} d k {e}^{i m ϕ} {e}^{i k z} [ a {I}_{m} ( \vert k \vert a ) {K}_{m} ( \vert k \vert ρ ) {J}_{z}^{m} ( k ) + b {I}_{m} ( \vert k \vert ρ ) {K}_{m} ( \vert k \vert b ) ( k ) ] \qquad ( 1.72 )$$

Using 1.40 and 1.69, the boundary conditions at ρ=b may be written as

$${\frac{1}{ρ} ( \frac{\partial }{\partial ρ} ( ρ {A}_{ϕ} ) - \frac{\partial {A}_{ρ}}{\partial ϕ} ) \vert}_{ρ = b} = 0 \qquad ( 1.73 )$$

$${( \frac{\partial {A}_{ρ}}{\partial z} - \frac{\partial {A}_{z}}{\partial ρ} ) \vert}_{ρ = b} = 0 \qquad ( 1.74 )$$

Using 1.70, 1.71 and 1.72, the pseudo-current density on the cylindrical wall of the passive shield is found to be

$$( k ) = - \frac{a {I}_{m}^{′} ( \vert k \vert a ) {K}_{m} ( \vert k \vert b )}{b {I}_{m} ( \vert k \vert b ) {K}_{m}^{′} ( \vert k \vert b )} {J}_{z}^{m} ( k ) \qquad ( 1.75 )$$

It follows from 1.40, 1.71, 1.71 and 1.72 that the magnetic field in the presence of a passive magnetic shielding material (e.g., a high permeability magnetic material) in the region ρ<a may be written as

$${B}_{ρ} ( ρ , ϕ , z ) = \frac{i {μ}_{0} a}{2 π} {\sum }_{m = - ∞}^{∞} {\int }_{- ∞}^{∞} d k k {e}^{i m ϕ} {e}^{i k z} {I}_{m}^{′} ( \vert k \vert ρ ) [ {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ] {J}_{ϕ}^{m} ( k ) \qquad ( 1.76 )$$

$${B}_{ϕ} ( ρ , ϕ , z ) = \frac{{μ}_{0} {a}^{2}}{2 πρ} {\sum }_{m = - ∞}^{∞} {\int }_{- ∞}^{∞} d k \vert k \vert {e}^{i m ϕ} {e}^{i k z} {I}_{m} ( \vert k \vert ρ ) [ {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ] {J}_{z}^{m} ( k ) \qquad ( 1.77 )$$

$${B}_{z} ( ρ , ϕ , z ) = - \frac{{μ}_{0} a}{2 π} {\sum }_{m = - ∞}^{∞} {\int }_{- ∞}^{∞} d k \vert k \vert {e}^{i m ϕ} {e}^{i k z} {I}_{m} ( \vert k \vert ρ ) [ {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ] {J}_{ϕ}^{m} ( k ) \qquad ( 1.78 )$$

In the specific case of the radius of the coil being equal to the radius of the passive magnetic shield, (a=b), these expressions may be further simplified using the relation 1.19, giving

$${B}_{ρ} ( ρ , ϕ , z ) = \frac{i {μ}_{0}}{2 π} {\sum }_{m = - ∞}^{∞} {\int }_{- ∞}^{∞} d k \frac{k}{\vert k \vert} {e}^{i m ϕ} {e}^{i k z} \frac{{I}_{m} ( \vert k \vert ρ )}{{I}_{m} ( \vert k \vert a )} {J}_{ϕ}^{m} ( k ) \qquad ( 1.79 )$$

$${B}_{ϕ} ( ρ , ϕ , z ) = \frac{{μ}_{0 a}}{2 πρ} {\sum }_{m = - ∞}^{∞} {\int }_{- ∞}^{∞} d k {e}^{i m ϕ} {e}^{i k z} \frac{{I}_{m} ( \vert k \vert ρ )}{{I}_{m} ( \vert k \vert a )} {J}_{z}^{m} ( k ) \qquad ( 1.8 )$$

$${B}_{z} ( ρ , ϕ , z ) = - \frac{{μ}_{0}}{2 π} {\sum }_{m = - ∞}^{∞} {\int }_{- ∞}^{∞} d k {e}^{i m ϕ} {e}^{i k z} \frac{{I}_{m} ( \vert k \vert ρ )}{{I}_{m} ( \vert k \vert a )} {J}_{ϕ}^{m} ( k ) \qquad ( 1.81 )$$

however, for generality this will be not be used (but it is noted that it may be used). Now, the effect of the planar end caps needs to be incorporated. Using 1.40 and 1.69, the boundary conditions on the magnetic field at z=±\hat{L}/2 may be written as

$${( \frac{1}{ρ} \frac{\partial {A}_{z}}{\partial ϕ} - \frac{\partial {A}_{ϕ}}{\partial z} ) \vert}_{z \pm \hat{L} / 2} = 0 \qquad ( 1.82 )$$

$${( \frac{\partial {A}_{ρ}}{\partial z} - \frac{\partial {A}_{z}}{\partial ρ} ) \vert}_{z \pm \hat{L} / 2} = 0 \qquad ( 1.83 )$$

In the below example, these boundary conditions are implemented through the method of mirror images. The resulting solution comprises an infinite number of reflected image currents giving a magnetic field with components of the form

$${B}_{ρ} ( ρ , ϕ , z ) = \frac{i {μ}_{0} a}{2 π} {\sum }_{p = - ∞}^{∞} {\sum }_{m = - ∞}^{∞} {\int }_{- ∞}^{∞} d k k {e}^{i m ϕ} {e}^{i k z} {I}_{m}^{′} ( \vert k \vert ρ ) [ {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ] {J}_{ϕ}^{m p} ( k ) \qquad ( 1.84 )$$

$${B}_{ϕ} ( ρ , ϕ , z ) = \frac{{μ}_{0} {a}^{2}}{2 πρ} {\sum }_{p = - ∞}^{∞} {\sum }_{m = - ∞}^{∞} {\int }_{- ∞}^{∞} d k \vert k \vert {e}^{i m ϕ} {e}^{i k z} {I}_{m} ( \vert k \vert ρ ) [ {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ] {J}_{z}^{m p} ( k ) \qquad ( 1.85 )$$

$${B}_{z} ( ρ , ϕ , z ) = - \frac{{μ}_{0} a}{2 π} {\sum }_{p = - ∞}^{∞} {\sum }_{m = - ∞}^{∞} {\int }_{- ∞}^{∞} d k \vert k \vert {e}^{i m ϕ} {e}^{i k z} {I}_{m} ( \vert k \vert ρ ) [ {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ] {J}_{ϕ}^{m p} ( k ) \qquad ( 1.86 )$$

$$where$$

$${J}_{ϕ}^{m p} ( k ) = \frac{1}{2 π} {\int }_{0}^{2 π} d {ϕ}^{′} {e}^{- i m {ϕ}^{′}} {\int }_{- ∞}^{∞} d {z}^{′} {e}^{- i k {z}^{′}} {J}_{ϕ}^{p} ( {ϕ}^{′} , {z}^{′} ) \qquad ( 1.87 )$$

$${J}_{z}^{m p} ( k ) = \frac{1}{2 π} {\int }_{0}^{2 π} d {ϕ}^{′} {e}^{- i m {ϕ}^{′}} {\int }_{- ∞}^{∞} d {z}^{′} {e}^{- i k {z}^{′}} {J}_{z}^{p} ( {ϕ}^{′} , {z}^{′} ) \qquad ( 1.88 )$$

As is usual for the method of mirror images, the image currents must therefore be adjusted such that any odd reflections, e.g., p=1, 3, 5, . . . etc., result in an axial current that opposes the original current source. This leads to an adjusted streamfunction of the form

$${φ}^{p} ( \text{} ( {ϕ}^{′} , {z}^{′} ) = ( {T}_{e} ( {z}^{′} ; {L}_{2} + p \hat{L} , {L}_{1} + p \hat{L} ) + {T}_{o} ( {z}^{′} ; - {L}_{1} + p \hat{L} , - {L}_{2} + p \hat{L} ) ) \times \{ - {( - 1 )}^{p} {\sum }_{n = 1}^{N} \frac{L}{n π} {P}_{n 0} cos ( \frac{n π ( {( - 1 )}^{p} ( {z}^{′} - p \hat{L} ) - {L}_{2} )}{{L}_{1} - {L}_{2}} ) \text{} + {( - 1 )}^{p} {\text{} \text{} \sum }_{n = 1}^{N} \text{} {\sum }_{m = 1}^{M} \frac{L}{n π} ( {P}_{n m} cos ( m {ϕ}^{′} + {Q}_{n m} sin ( m {ϕ}^{′} ) ) sin ( \frac{n π ( {( - 1 )}^{p} ( {z}^{′} - p \hat{L} ) - {L}_{2} )}{{L}_{1} - {L}_{2}} ) \} \qquad ( 1.89 )$$

$$( {T}_{e} ( {z}^{′} ; {L}_{2} + p \hat{L} , {L}_{1} + p \hat{L} ) = ( H ( {z}^{′} - {L}_{2} - p \hat{L} ) - H ( {z}^{′} - {L}_{1} - p \hat{L} ) ) ( \frac{1 - {( - 1 )}^{p + 1}}{2} ) \qquad ( 1.9 )$$

$${T}_{o} ( {z}^{′} ; - {L}_{1} + p \hat{L} , - {L}_{2} + p \hat{L} ) ) = ( H ( {z}^{′} - {L}_{1} - p \hat{L} ) - H ( {z}^{′} - {L}_{2} - p \hat{L} ) ) ( \frac{1 - {( - 1 )}^{p}}{2} ) \qquad ( 1.91 )$$

where H(x) is the Heaviside function, resulting in an axial current density

$${J}_{z}^{p} ( \text{} ( {ϕ}^{′} , {z}^{′} ) = ( {T}_{e} ( {z}^{′} ; {L}_{2} + p \hat{L} , {L}_{1} + p \hat{L} ) + {T}_{o} ( {z}^{′} ; - {L}_{1} + p \hat{L} , - {L}_{2} + p \hat{L} ) ) \times {\sum }_{n = 1}^{N} {\sum }_{m = 1}^{M} {( - 1 )}^{p} \frac{m L}{n π a} [ {P}_{n m} sin ( m {ϕ}^{′} ) - {Q}_{n m} cos ( m {ϕ}^{′} ) ] sin ( \frac{n π ( {( - 1 )}^{p} ( {z}^{′} - p \hat{L} ) - {L}_{2 )}}{{L}_{1} - {L}_{2}} ) \qquad ( 1.92 )$$

which has zero value at z′=±L_{1,2}+p\hat{L} for even and odd reflections respectively. The azimuthal component of the current density is given by

$${J}_{ϕ}^{p} ( {ϕ}^{′} , {z}^{′} ) = ( {T}_{e} ( {z}^{′} ; {L}_{2} + p \hat{L} , {L}_{1} + p \hat{L} ) + {T}_{o} ( {z}^{′} ; - {L}_{1} + p \hat{L} , - {L}_{2} + p \hat{L} ) ) \times \{ {\sum }_{n = 1}^{N} {P}_{n 0} sin ( \frac{n π ( {( - 1 )}^{p} ( {z}^{′} - p \hat{L} ) - {L}_{2} )}{{L}_{1} - {L}_{2}} ) + {\sum }_{n = 1}^{N} {\sum }_{m = 1}^{M} ( {P}_{n m} cos ( m {ϕ}^{′} + {Q}_{n m} sin ( m {ϕ}^{′} ) ) cos ( \frac{n π ( {( - 1 )}^{p} ( {z}^{′} - p \hat{L} ) - {L}_{2} )}{{L}_{1} - {L}_{2}} ) \} \qquad ( 1.93 )$$

Substituting 1.92 and 1.93 into 1.84, 1.85 and 1.86, it is found that the magnetic field is given by

$${B}_{ρ} ( ρ , ϕ , z ) = {\sum }_{n = 1}^{N} {P}_{n 0} \tilde{{F}_{n}} ( ρ , z ) + {\sum }_{n = 1}^{N} {\sum }_{m = 1}^{M} ( {P}_{n m} {\tilde{G}}_{n m}^{p} ( ρ , z ) + {Q}_{n m} {\tilde{G}}_{n m}^{q} ( ρ , z ) ) \qquad ( 1.94 )$$

$${B}_{ϕ} ( ρ , ϕ , z ) = {\sum }_{n = 1}^{N} {\sum }_{m = 1}^{M} ( {P}_{n m} {\tilde{H}}_{n m}^{p} ( ρ , z ) + {Q}_{n m} {\tilde{H}}_{n m}^{q} ( ρ , z ) ) \qquad ( 1.95 )$$

$${B}_{Z} ( ρ , ϕ , z ) = {\sum }_{n = 1}^{N} {P}_{n 0} {\tilde{D}}_{n} ( ρ , z ) + {\sum }_{n = 1}^{N} {\sum }_{m = 1}^{M} ( {P}_{n m} {\tilde{S}}_{n m}^{p} ( ρ , z ) + {Q}_{n m} {\tilde{S}}_{n m}^{q} ( ρ , z ) ) \qquad ( 1.96 )$$

$$where ,$$

$${F}_{n} ( ρ , z ) = {\sum }_{p = - ∞}^{∞} {\int }_{- ∞}^{∞} {dkI}_{0}^{′} ( \vert k \vert ρ ) ( {K}_{0}^{′} ( \vert k \vert a ) - \frac{{I}_{0}^{′} ( \vert k \vert a ) {K}_{0} ( \vert k \vert b )}{{I}_{0} ( \vert k \vert b )} ) {C}_{n p}^{1} ( k , z ) \qquad ( 1.97 )$$

$${G}_{n m} ( ρ , z ) = {\sum }_{p = - ∞}^{∞} {\int }_{- ∞}^{∞} {dkI}_{m}^{′} ( \vert k \vert ρ ) ( {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ) {C}_{n p}^{2} ( k , z ) \qquad ( 1.98 )$$

$$\begin{matrix}{G}_{n m}^{p} ( ρ , z ) = cos ( m ϕ ) {G}_{n m} ( ρ , z ) , & {G}_{n m}^{q} ( ρ , z ) = sin ( m ϕ ) {G}_{n m} ( ρ , z )\end{matrix} \qquad ( 1.99 )$$

$${H}_{n m} ( ρ , z ) = {\sum }_{p = - ∞}^{∞} {\int }_{- ∞}^{∞} dkm {I}_{m} ( k ρ ) ( {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ) {C}_{n p}^{3} ( k , z ) \qquad ( 1.1 )$$

$$\begin{matrix}{H}_{n m}^{p} ( ρ , z ) = sin ( m ϕ ) {H}_{n m} ( ρ , z ) , & {H}_{n m}^{q} ( ρ , z ) = - cos ( m ϕ ) {H}_{n m} ( ρ , z )\end{matrix} \qquad ( 1.101 )$$

$${D}_{n} ( ρ , z ) = {\sum }_{p = - ∞}^{∞} {\int }_{- ∞}^{∞} dk {I}_{0} ( k ρ ) ( {K}_{0}^{′} ( \vert k \vert a ) - \frac{{I}_{0}^{′} ( \vert k \vert a ) {K}_{0} ( \vert k \vert b )}{{I}_{0} ( \vert k \vert b )} ) {C}_{n p}^{4} ( k , z ) \qquad ( 1.102 )$$

$${S}_{n m} ( ρ , z ) = {\sum }_{p = - ∞}^{∞} {\int }_{- ∞}^{∞} {dkI}_{m} ( k ρ ) ( {K}_{m}^{′} ( \vert k \vert a ) - \frac{{I}_{m}^{′} ( \vert k \vert a ) {K}_{m} ( \vert k \vert b )}{{I}_{m} ( \vert k \vert b )} ) {C}_{n p}^{5} ( k , z ) \qquad ( 1.103 )$$

$$\begin{matrix}{S}_{n m}^{p} ( ρ , z ) = cos ( m ϕ ) {S}_{n m} ( ρ , z ) , & {S}_{n m}^{q} ( ρ , z ) = sin ( m ϕ ) {S}_{n m} ( ρ , z )\end{matrix} \qquad ( 1.104 )$$

$$where$$

$${C}_{np}^{1} ( k , z ) = \frac{i {μ}_{0} an ( {L}_{1} - {L}_{2} )}{2} {ke}^{ik ( z - p \hat{L} )} ( \frac{{e}^{- {( - 1 )}^{P} {ikL}_{2}} + {( - 1 )}^{n + 1} {e}^{- {( - 1 )}^{P} {ikL}_{1}}}{{n}^{2} {π}^{2} - {( {L}_{1} - {L}_{2} )}^{2} {k}^{2}} ) \qquad ( 1.105 )$$

$${C}_{np}^{2} ( k , z ) = \frac{i {( - 1 )}^{p} ( {L}_{1} - {L}_{2} ) k}{n π} {C}_{np}^{1} ( k , z ) \qquad ( 1.106 )$$

$${C}_{np}^{3} ( k , z ) = \frac{i {( - 1 )}^{p} ( {L}_{1} - {L}_{2} ) \vert k \vert}{n π k ρ} {C}_{np}^{1} ( k , z ) \qquad ( 1.107 )$$

$${C}_{np}^{4} ( k , z ) = \frac{i \vert k \vert}{k} {C}_{np}^{1} ( k , z ) \qquad ( 1.108 )$$

$${C}_{np}^{5} ( k , z ) = - \frac{{( - 1 )}^{p} ( {L}_{1} - {L}_{2} ) \vert k \vert}{n π} {C}_{np}^{1} ( k , z ) \qquad ( 1.109 )$$

As outlined previously, the Fourier coefficients may be solved using an optimisation process (for example a least squares minimisation, optionally incorporating a regularisation term).

Whilst the example method outlined above assumes infinite permeability of the cylinder, magnetic shields comprising a passive magnetic shielding material having a relative permeability of substantially 1000 or greater, and a winding configuration optimised in accordance with the invention, will generate a magnetic field that is accurate to within substantially 99% of the magnetic field produced by the system optimised assuming infinite permeability. Magnetic shields having a winding configuration optimised in accordance with the invention and comprising a passive magnetic shielding material having a relative permeability of less than substantially 1000 may generate magnetic fields with a greater difference from the target field, but may still be useful in providing magnetic shielding.

A similar approach to that described above may be used in order to optimise winding configurations accounting for the interactions with a passive magnetic shielding material to produce magnetic fields other than constant magnetic fields, for example linear ‘gradient’ fields or quadratic ‘curvature’ fields. This is discussed in further detail below.

It will also be appreciated that depending on the region within a cylindrical passive magnetic shield over which the optimisation of the winding is to be considered (for example, if the cylindrical passive magnetic shield has a high aspect ratio, with the optimised region located near the centre of the cylindrical passive magnetic shield with respect to its axial direction), the planar end caps of the cylindrical passive magnetic shield may be disregarded for the purposes of optimising the winding configuration. In such embodiments, the boundary conditions relating to the planar end caps need not be implemented, and the optimisation process performed accordingly. Therefore, the optimisation may alternatively be performed modelling the passive magnetic shield as an open cylindrical structure, rather than a closed cylindrical structure.

It will further be appreciated that a similar approach to that described above may be employed to optimise a winding configuration for use with a passive magnetic shield having a geometry other than a cylindrical geometry. By employing the same principle of constructing a physically relevant function (for example, a Green's function), or discrete approximation thereof, for the interior geometry of the passive magnetic shield, and implementing one or more appropriate boundary conditions (depending on the geometry of the passive magnetic shield) to ensure the value of the magnetic field attains the correct physical limit as the winding approaches the interior surface of the passive magnetic shield.

In alternative embodiments, a finite element analysis approach is employed instead of the Fourier analysis illustrated in the above example. In some embodiments, the governing equations and boundary conditions as shown in 1.84 to 1.86 are used in a numerical calculation with a finite element current distribution.

In a further alternative embodiment, rather than determining optimal surface currents as described in the above example, one or more discrete winding elements are specified a priori and one or more parameters optimised to produce a specified magnetic field. This approach can sometimes be simpler than the surface currents approach discussed above, for example depending on engineering constraints of the magnetic shield in question. This alternative approach makes use of some of the method described in detail above (up to 1.88). The boundary conditions are implemented for a finite length perfect magnetic conducting (i.e., infinite magnetic permeability) cylinder of length 2L and outer radius b enclosing an interior cylindrical region of radius a.

For simplicity, the case a=b is discussed below. The resulting field in the z-direction is given by

$${B}_{z} ( ρ , ϕ , z ) = \frac{{μ}_{0}}{2 π} {\sum }_{p = - ∞}^{∞} {\sum }_{m = - ∞}^{∞} {\int }_{- ∞}^{∞} d k {e}^{i m ϕ} {e}^{i k z} \frac{{I}_{m} ( \vert k \vert ρ )}{{I}_{m} ( \vert k \vert a )} {J}_{ϕ}^{m p} ( k ) \qquad ( 1.11 )$$

The simplest discrete winding element is now considered—a circle. For a single circular loop with current Iᵢ, of radius a and z location d inside the cylinder, the resulting field in the z-direction may be written as

$${B}_{z} ( ρ , ϕ , z ) = \frac{{μ}_{0} {I}_{i}}{2 π} {\sum }_{p = - ∞}^{∞} {\int }_{- ∞}^{∞} d k {e}^{i k ( z - {( - 1 )}^{{P}_{{d}_{i} - 2 {L}_{p}}} )} \frac{{I}_{0} ( \vert k \vert ρ )}{{I}_{0} ( \vert k \vert a )} \qquad ( 1.111 )$$

A simple gradient field may be generated in the z-direction using a single pair of circular loops with currents flowing in opposite direction (an anti-Helmholtz arrangement). Using 1.111, the magnetic field produced by such a pair of coils separated by a distance along the z-direction of 2d from the origin may be written as

$${B}_{z} ( ρ , ϕ , z ) = \frac{- 2 i {μ}_{0} I}{π} {\int }_{- ∞}^{∞} d k {e}^{i k z} \frac{{I}_{0} ( \vert k \vert ρ )}{{I}_{0} ( \vert k \vert a )} sin ( k d ) ( 1 - 2 {\sum }_{p = 1}^{∞} {( - 1 )}^{p + 1} cos ( 2 L p k ) ) \qquad ( 1.112 )$$

Performing the integral over k it is found that

$${B}_{z} ( ρ , ϕ , z ) = 2 {μ}_{0} I {\sum }_{p = - ∞}^{∞} sin ( \frac{π p z}{2 L} ) sin ( \frac{π pd}{2 L} ) \frac{{I}_{0} ( \vert \frac{π p}{2 L} \vert ρ )}{{I}_{0} ( \vert \frac{π p}{2 L} \vert a )} ( 1 - {( - 1 )}^{p} ) \qquad ( 1.113 )$$

Taylor expanding the spatially varying terms using

$${I}_{0} ( \frac{k ρ}{a} ) = 1 + \frac{{k}^{2} {ρ}^{2}}{4 {a}^{2}} + O ( {ρ}^{4} ) + … \qquad ( 1.114 )$$

$$sin ( \frac{kz}{a} ) = \frac{k z}{a} - \frac{{k}^{3} {z}^{3}}{6 {a}^{3}} + O ( {z}^{4} ) - … \qquad ( 1.115 )$$

it is seen that

$${B}_{z} ( ρ , ϕ , z ) = 4 {μ}_{0} {I}_{i} {\sum }_{p = 1}^{∞} p \frac{sin ( \frac{π dp}{2 L} )}{{I}_{0} ( \frac{π ap}{2 L} )} ( 1 - {( - 1 )}^{p} ) [ \frac{π z}{2 L} + {p}^{2} ( \frac{{π}^{3} z {ρ}^{2}}{32 {L}^{3}} - \frac{{π}^{3} {z}^{3}}{48 {L}^{3}} ) + {p}^{4} … ] \qquad ( 1.116 )$$

1.116 may be simplified to

$${B}_{z} ( ρ , ϕ , z ) = \frac{4 {μ}_{0} π I}{2 L} ( z {B}_{1} + ( \frac{{π}^{2} z {ρ}^{2}}{16 {L}^{2}} - \frac{{π}^{2} {z}^{3}}{24 {L}^{2}} ) {B}_{3} + … ) \qquad ( 1.117 )$$

where B₁, B₃, . . . B₂ₙ₋₁ are the magnitudes of the linear, cubic, etc. fields generated by the asymmetric coil set up. In order to remove cubic variations in the field it is required that B₃=0, resulting, in order to cancel cubic variations in the magnetic field, in

$${B}_{3} = {\sum }_{p = 1}^{∞} {p}^{3} \frac{sin ( \frac{π dp}{2 L} )}{{I}_{0} ( \frac{π ap}{2 L} )} ( 1 - {( - 1 )}^{p} ) = 0 \qquad ( 1.118 )$$

which may be generalised for N pairs of loops resulting in the set of simultaneous equations

$$\begin{matrix}{\sum }_{i = 1}^{N} {I}_{i} {\sum }_{p = 1}^{∞} {p}^{2 n + 1} \frac{sin ( \frac{π dp}{2 L} )}{{I}_{0} ( \frac{π ap}{2 L} )} ( 1 - {( - 1 )}^{P} ) = 0 , & n ∈ ℤ : n ∈ [ 1 , N ]\end{matrix} \qquad ( 1.119 )$$

The ratios of a and d may now be determined in order to eliminate the leading order errors in the desired magnetic field. In the specific embodiment described above, the free parameters optimised are the spacing d and the relationship between the spacing d and the radius a of the circular loop winding elements. Other free parameters may be optimised, for example, an orientation, shape, size or placement of a discrete winding element, to generate a desired magnetic field. Additionally or alternatively, relationships between two or more free parameters of the discrete winding elements may be optimised to generate a desired magnetic field.

For an effective approach to magnetic field design, the formation of any physical field must be understood from a mathematical basis. Starting from the fundamental equations for static magnetic fields, as the magnetic field, H, and the electric field, E, may be expressed in terms of the vector potential, A, as well as the scalar potential, Φ, any transformation of these variables leads to an arbitrary choice of gauge in the way the potential is defined. As the problems considered here are in the static regime, using the Coulomb gauge is the most logical choice for simplicity, and so, unless stated, this gauge is used throughout. The Maxwell equations that describe static magnetic fields, through a volume within which no current passes, are given by Gauss' and Ampere's law respectively,

∇·H=∇∧H=0 (1.120)

with the magnetic induction, B, being related to the scalar and vector potential by

B=−∇Φ=∇∧A (1.121)

The magnetic induction may be related to the magnetic field through the use of the magnetic permeability, μ. For free space, this relation takes the simplified form of

B=μ₀(H+M) (1.122)

Where M is the magnetisation, relating to the bound current density of a magnetised surface

J_{b}=∇∧M (1.123)

Upon substitution of 1.111 into 1.110 the following is obtained

∇·∇Φ=∇∧∇∧A=0 (1.124)

Using vector identities with choice of gauge, ∇·A=0, it is seen that the scalar and vector potential satisfy the partial differential equation (PDE),

∇²Φ=∇²A=0 (1.125)

It then follows that

∇²H=∇²B=0 (1.126)

Laplace's may be solved by a transformation into spherical polar coordinates such that the Laplacian of a function is given by

$${∇}^{2} f = \frac{1}{{r}^{2}} \frac{\partial }{\partial r} ( {r}^{2} \frac{\partial f}{\partial r} ) + \frac{1}{{r}^{2} {sin}^{2} θ} \frac{{\partial }^{2} f}{\partial {ϕ}^{2}} + \frac{1}{{r}^{2} sin θ} ( sin θ \frac{\partial f}{\partial θ} ) \qquad ( 1.127 )$$

Separation of variables shows that the real solutions take the form

$$f = {\sum }_{n = 1}^{∞} {\sum }_{m = - n}^{n} {C}_{n m} ( \begin{matrix}{r}_{<}^{n} \\ {r}_{>}^{- n - 1}\end{matrix} ) {P}_{n m} ( cos θ ) ( \begin{matrix}cos ( m ϕ ) \\ sin ( m ϕ )\end{matrix} ) , \begin{matrix}m \geq 0 \\ m < 0\end{matrix} \qquad ( 1.128 )$$

where Pₙₘ(x) are Ferrer's associated Legendre polynomials of the nth order and mth degree, with r_{<} and r_{>} relating to the interior or exterior region of a defined spherical topology enclosing a current source. An orthogonal basis may be generated for both the scalar and vector magnetic potential as well as the individual magnetic field components and intensities. From this, the physical orthogonal set of magnetic fields may be constructed from the relationship between the scalar potential and the magnetic field. For a magnetic field generated on the interior of a surface current (r_{<} case), the magnetic field may be expanded as a summation of spherical harmonic fields. The harmonics produced, up to and including n=3, may be given by

Constant “Bias” Fields

$$n = 1 \to \{ \begin{matrix}B ( x , y , z ) = \hat{x} , m = 1 \\ B ( x , y , z ) = \hat{z} , m = 0 \\ B ( x , y , z ) = \hat{y} , m = - 1\end{matrix} \qquad ( 1.129 )$$

Linear “Gradient” Fields

$$n = 2 \to \{ \begin{matrix}B ( x , y , z ) = x \hat{x} - y \hat{y} , m = 2 \\ B ( x , y , z ) = z \hat{x} + x \hat{z} , m = 1 \\ B ( x , y , z ) = - x \hat{x} - y \hat{y} + 2 z \hat{z} , m = 0 \\ B ( x , y , z ) = z \hat{y} + y \hat{z} , m = - 1 \\ B ( x , y , z ) = y \hat{x} + x \hat{y ,} m = - 2\end{matrix} \qquad ( 1.13 )$$

Quadratic “Curvature” Fields

$$n = 2 \to \{ \begin{matrix}B ( x , y , z ) = ( {x}^{2} - {y}^{2} ) \hat{x} - 2 x y \hat{y ,} m = 3 \\ B ( x , y , z ) = 2 x z \hat{x} - 2 y z \hat{y} + ( {x}^{2} - {y}^{2} ) \hat{z} , m = 2 \\ B ( x , y , z ) = ( 4 {z}^{2} - 3 {x}^{2} - {y}^{2} ) \hat{x} - 2 x y \hat{y} + 8 x z \hat{z} , m = 1 \\ B ( x , y , z ) = - 2 x z \hat{x} - 2 y z \hat{y} + ( 2 {z}^{2} - {x}^{2} - {y}^{2} ) \hat{z ,} m = 0 \\ B ( x , y , z ) = - 2 x y \hat{x} + ( 4 {z}^{2} - {x}^{2} - 3 {y}^{2} ) \hat{y} + 8 y z \hat{z} , m = - 1 \\ B ( x , y , z ) = y z \hat{x} + x z \hat{y} + x y \hat{z} , m = - 2 \\ B ( x , y , z ) = 2 x y \hat{x} - ( {x}^{2} - {y}^{2} ) \hat{y} m = - 3\end{matrix} \qquad ( 1.131 )$$

Through the use of this orthogonal set, a cancellation system may be constructed to null magnetic fields efficiently. This may be extended to higher order fields as needed, although the relative magnitude of an external field of the same order and degree decreases rapidly as n increases. Due to this, a limited set of spherical harmonics may be used to facilitate the bulk of the cancellation. Winding configurations may be optimised, for example, to generate one of the spherical harmonic fields outlined above.

Existing magnetic shields typically comprise passive magnetic shielding material, and a winding configuration designed, or optimised, not in the presence of the passive magnetic shielding.

Constant field winding configurations designed to fit the internal cavity of a substantially cylindrical magnetic shield having internal cavity length of 16.4 cm and an internal cavity diameter of 14.4 cm are now presented. A comparison is performed using two winding configurations—one configuration optimised omitting the interaction with the passive magnetic shielding material (e.g., Mu-metal®), and one configuration optimised accounting for the interaction with the passive magnetic shielding material.

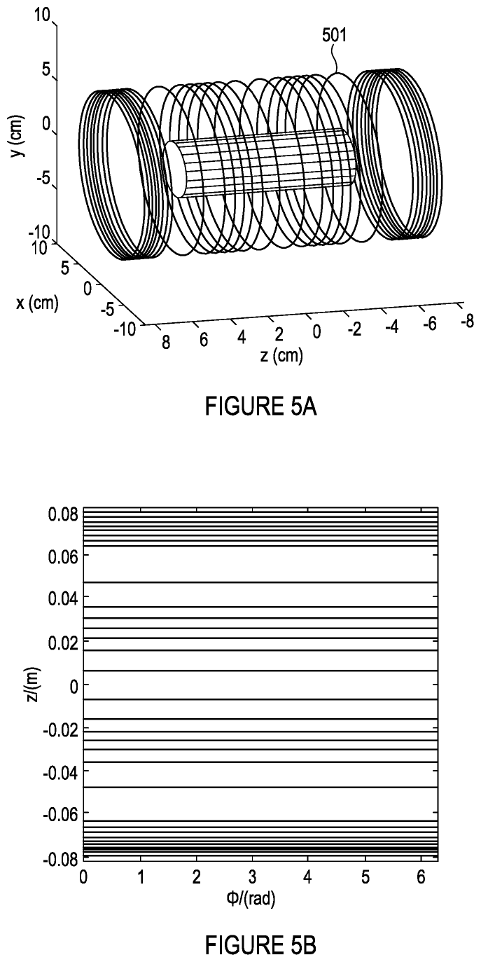

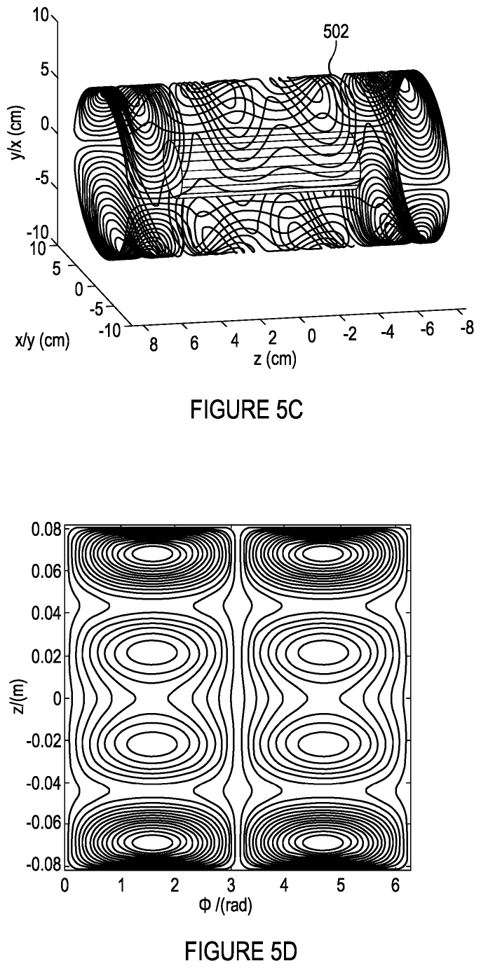

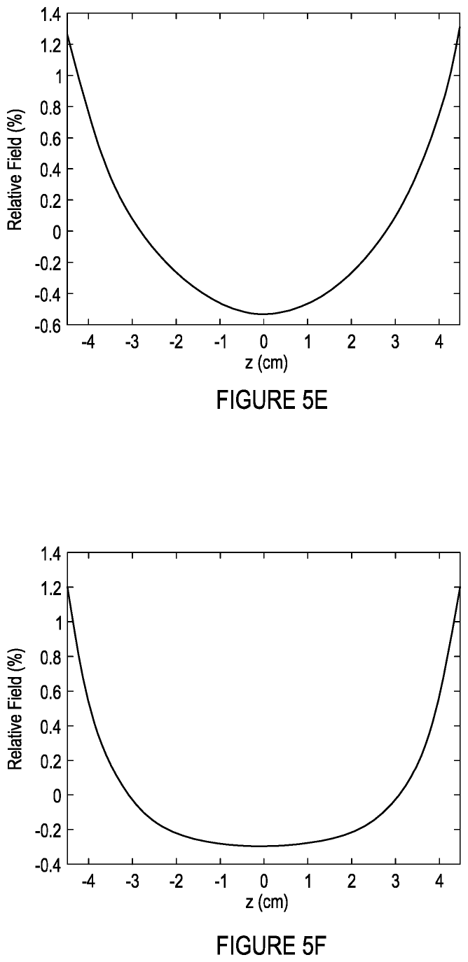

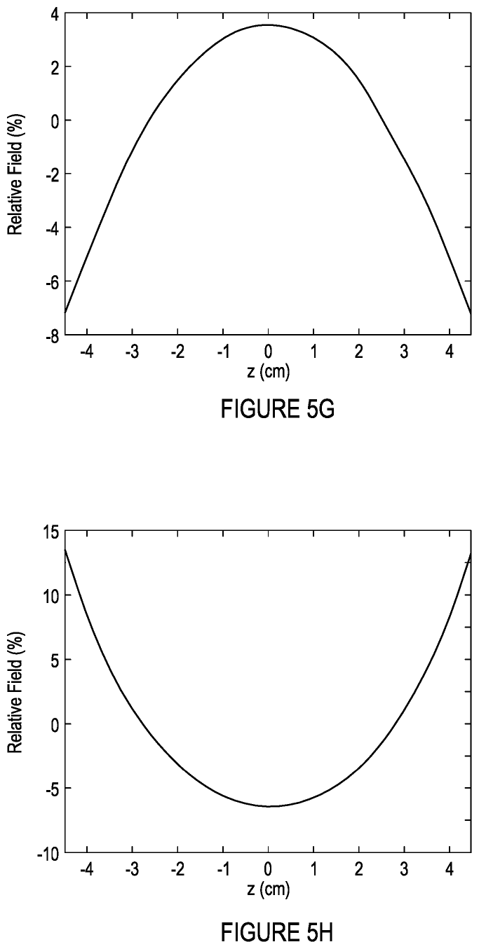

Firstly, winding configurations optimised omitting the interaction with the passive magnetic shielding material are considered. FIG. 5A shows an optimised (omitting the interaction with the passive magnetic shielding material) constant field winding 501 for the z-direction, n=1,m=0 (1.129). FIG. 5B shows a geometry of the winding 501 plotted versus angular position, ϕ, around the coil and z for clarity. FIG. 5C shows an optimised (omitting the interaction with the passive magnetic shielding material) constant field winding 502 for the y/x direction, n=1,m=1/−1 (1.129). FIG. 5D shows a geometry of the winding 502 plotted versus angular position, ϕ, around the coil and z for clarity. The windings 501, 502 are optimised over a region of length 9 cm and diameter 6 cm (i.e., a region having a volume of over 1000 cm³), represented by the cylindrical region displayed within the windings 501, 502 as shown in FIGS. 5A and 5C respectively.

The resulting relative field homogeneities of the windings 501, 502 are shown in FIGS. 5E and 5F respectively. FIG. 5E shows a plot of relative field variation (in %) as a function of distance from the central point (indicated by relative position of zero in the plot of FIG. 5E) of the space within the winding 501, along the z-axis, for the winding 501. FIG. 5F shows a plot of relative field variation (in %) as a function of distance from the central point (indicated by relative position of zero in the plot of FIG. 5F) of the space within the winding 502, along the z-axis, for the winding 502. The field homogeneities are given by 100×(1−Bᵢ), where Bᵢ is the unitary magnetic field in a given direction i=x,y,z (e.g., Bₓ=1, B_{y}=0, B_{z}=0).

The approximated relative field homogeneities of the windings 501, 502 are found when those windings 501, 502 are enclosed in a capped Mu-metal® cylinder of the same length and diameter of the windings 501, 502, and calculated using the method of mirror images (1.84 to 1.86). The approximated relative field homogeneities for the winding 501 and the winding 502 are shown in FIGS. 5G and 5H respectively. It can be seen that the effect of the passive magnetic shielding material on the relative magnetic field homogeneity for both z and y/x constant field coils decreases the relative homogeneity substantially ten-fold. In other words, the windings 501, 502 perform measurably worse when in the presence of passive magnetic shielding material. This can be seen by comparing FIG. 5E with FIG. 5G, and by comparing FIG. 5F with FIG. 5H.

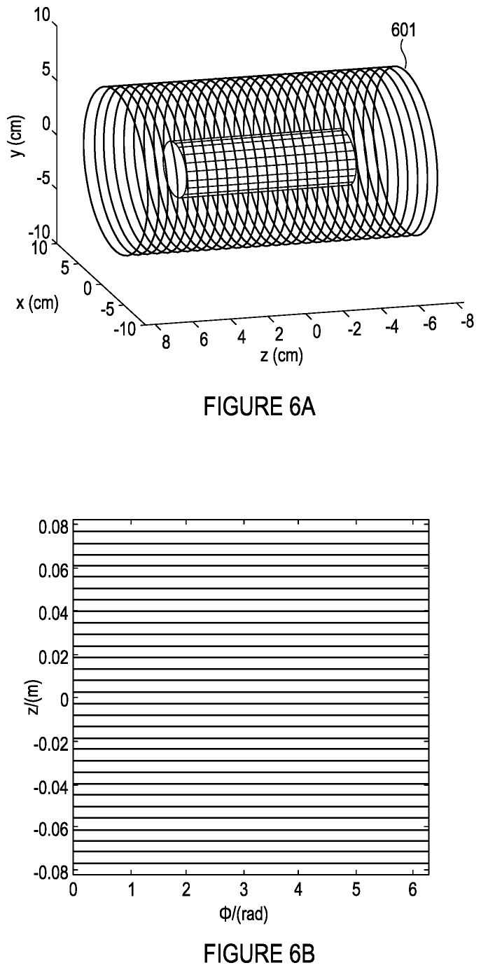

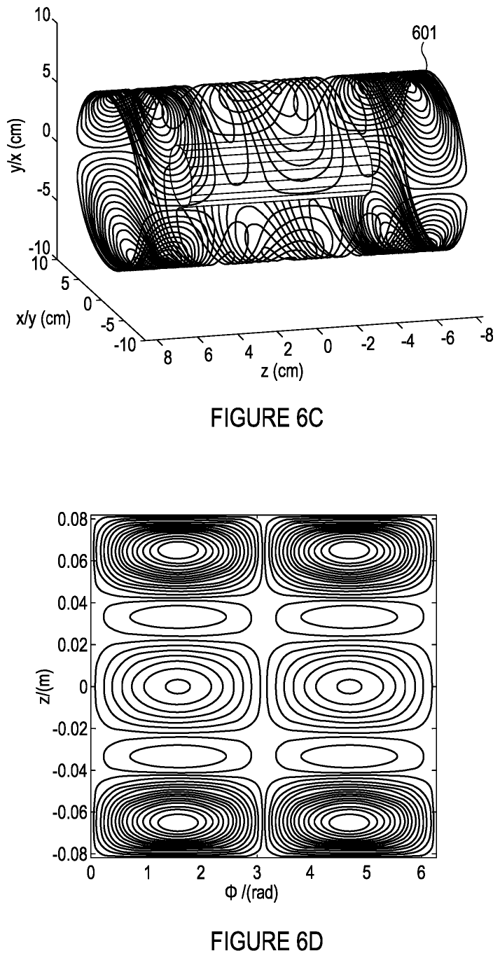

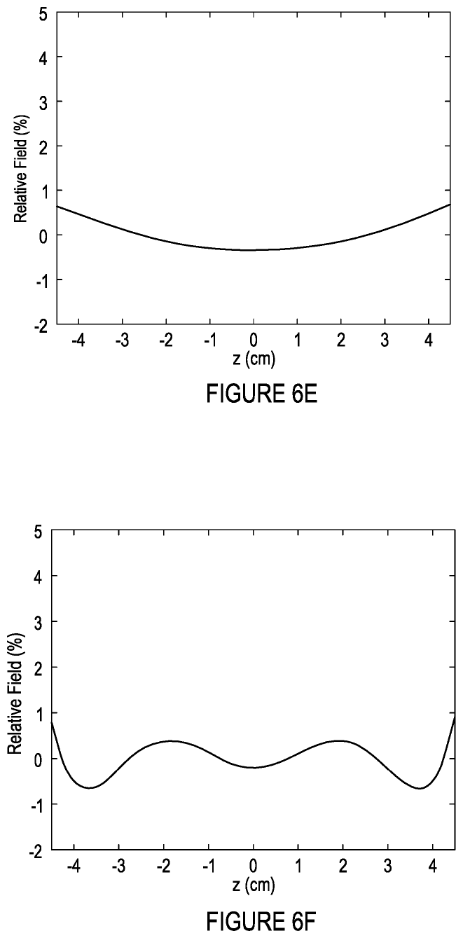

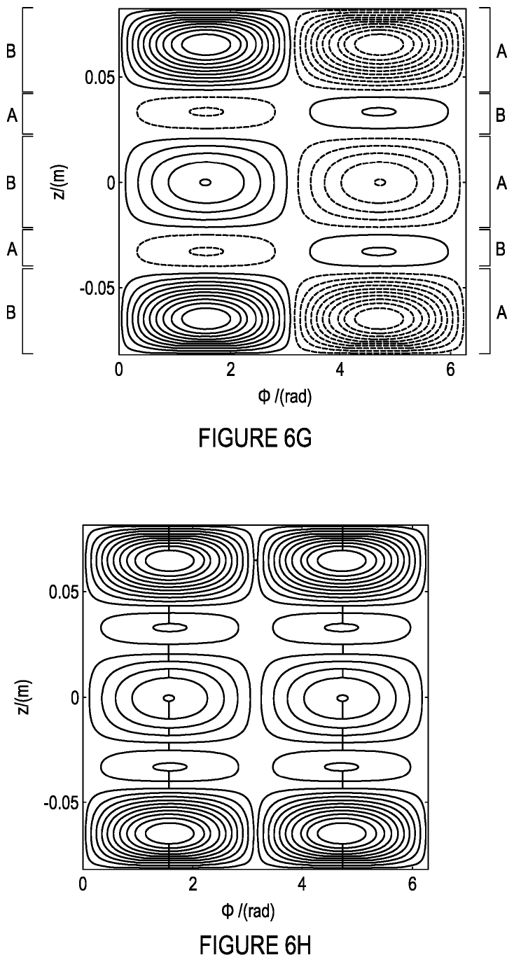

Now, winding configurations optimised including the interaction with passive magnetic shielding material (e.g., Mu-metal®) are presented. FIG. 6A shows an optimised (including the interaction with passive magnetic shielding material) constant field winding 601 for the z-direction, n=1,m=0 (1.129). FIG. 6B shows a geometry of the winding 601 plotted versus angular position, ϕ, around the coil and z for clarity. FIG. 6C shows an optimised (including the interaction with passive magnetic shielding material) constant field winding 602 for the y/x direction. FIG. 6D shows a geometry of the winding 602 plotted versus angular position, ϕ, around the coil and z for clarity. In the embodiment shown, the windings 601, 602 are optimised using the method outlined above (implementing relevant boundary conditions to account for the passive magnetic shielding material, and determining optimal surface currents). The windings 601, 602 are optimised over a region of length 9 cm and diameter 6 cm (i.e., a region having a volume of over 1000 cm³), represented by the cylindrical region displayed within the windings 601, 602 as shown in FIGS. 6A and 6C respectively.

The relative field homogeneities of the windings 601, 602, when enclosed in a capped Mu-metal® cylinder of the same length and diameter of the coil, are shown in FIGS. 6E and 6F respectively. FIG. 6E shows a plot of relative field variation (in %) as a function of distance from the central point (indicated by relative position of zero in the plot of FIG. 6E) of the space within the winding 601, along the z-axis, for the winding 601. FIG. 6F shows a plot of relative field variation (in %) as a function of distance from the central point (indicated by relative position of zero in the plot of FIG. 6F) of the space within the winding 602, along the z-axis, for the winding 602. The relative field homogeneities are calculated using the method of mirror images (1.84 to 1.86). It will be noted that because the optimisation of windings 601, 602 accounts for the interaction of the windings 601, 602 with the passive magnetic shielding material, the performance (for example, the field homogeneity) of the windings 601, 602 will be noticeably or measurably worse when not in the presence of passive magnetic shielding material (similar but opposite to the behaviour of the windings 501, 502). The field produced by a winding optimised accounting for the interactions with passive magnetic shielding material (e.g., windings 601, 602) will be more similar to a desired field (e.g., the desired field the optimisation is aimed towards producing) when the winding is in the presence of passive magnetic shielding material than when the winding is not in the presence of passive magnetic shielding material. This is true for uniform fields, linear ‘gradient’ fields, quadratic ‘curvature’ fields, and higher order fields. In the particular case of a uniform field, the field produced by such a winding (e.g., windings 601, 602) will be more uniform in the presence of passive magnetic shielding material than not in the presence of passive magnetic shielding material.

FIG. 6G shows the direction of current flow in the various regions of the optimised winding configuration shown in FIG. 6D. The different loops indicated A and B in FIG. 6G indicate counter-flowing current. Current flowing in regions labelled A flows in the opposite direction to current flowing in regions labelled B. FIG. 6H shows an example of how the different loops of the optimised winding configuration can be connected together to enable counter-flowing current to flow throughout the winding to produce a desired magnetic field.

A comparison of the winding configurations optimised omitting (windings 501, 502) or including (windings 601, 602) the interaction with a passive magnetic shielding material reveals drastically different winding geometries/configurations. Moreover, the resulting relative field homogeneity obtained using a winding for which the interactions with the passive magnetic shielding material are taken into account ab initio (windings 601, 602) show a substantially ten-fold reduction of unwanted field inhomogeneity (see FIGS. 6E, 6F) when compared to a winding optimised without the interaction of a passive magnetic shielding material (windings 501, 502, see FIGS. 5G and 5H). Winding configurations optimised to account for the interaction of the winding with a passive magnetic shielding material may therefore allow for a substantial reduction (e.g., a substantially three-fold reduction) in the volume of passive magnetic shielding material used to achieve the same region of field homogeneity. This allows the length of the cylinder (e.g., the overall length of the shield) to be reduced. Consequently, the optimisation method outlined above offers prospects for a magnetic shield which achieves high-specification performance whilst reducing size, weight and cost relative to existing commercial magnetic shields.

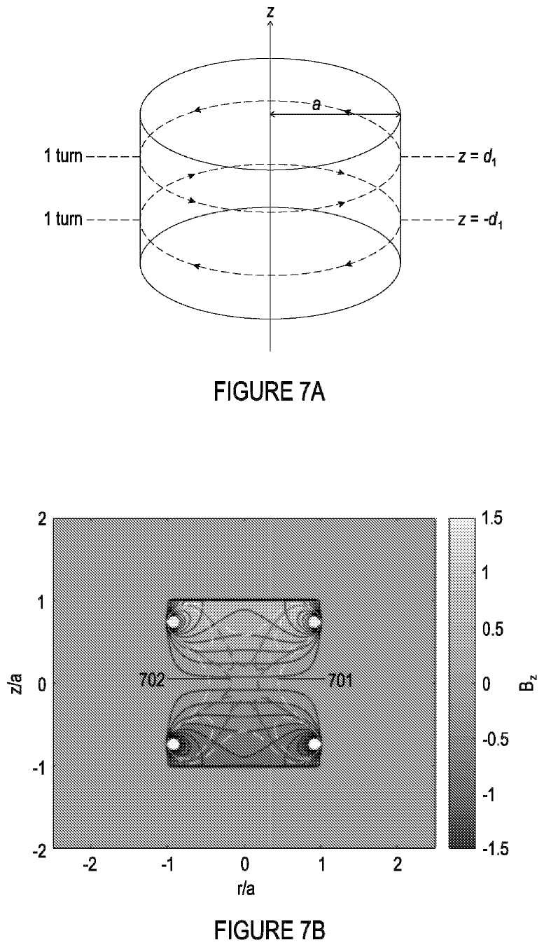

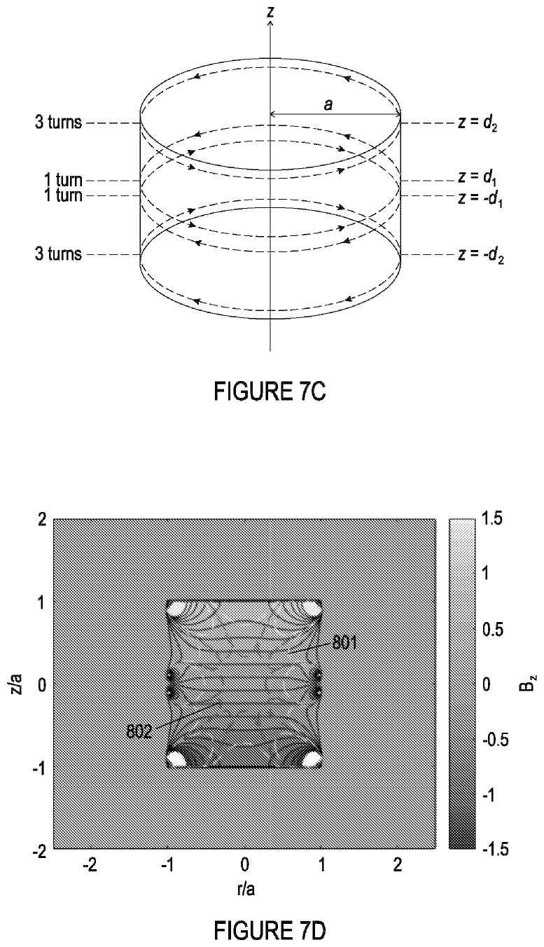

FIG. 7A shows an adjusted anti-Helmholtz coil arrangement inside a finite cylinder of infinite magnetic permeability optimised using the discrete element parameter optimisation method discussed above. FIG. 7A shows a pair of single-turn coils each having a radius a, separated in the z-direction by a distance of 2d₁, where solving 1.118 to remove third-order variations in the B_{z} field yields d₁=0.737a. FIG. 7B shows a plot of absolute magnetic field generated by the coil arrangement shown in FIG. 7A. The horizontal axis indicates a distance across the diameter of the cylinder relative to the radius a of the coils. The vertical axis indicates a distance along a longitudinal length of the cylinder relative to the radius a of the coils. The colour scale in FIG. 7B indicates values of the magnetic field strength produced by the coil arrangement in FIG. 7A. The corresponding variation in magnetic field strength throughout the space enclosed by the coils clearly illustrates a substantially linear gradient field. The dashed lines 701 and 702 indicate areas inside the space enclosed by the coils in which a deviation from linearity of the magnetic gradient field are respectively ≤5% and ≤0.1%.

FIG. 7C shows another adjusted anti-Helmholtz coil arrangement inside a finite cylinder of infinite magnetic permeability optimised using the discrete element parameter optimisation method discussed above. FIG. 7C shows a pair of single-turn coils each having a radius a, separated by a distance of 2d₁, (where d₁=0.106a), and a pair of three-turn coils each having a radius a, separated by a distance of 2d₂ (where d₂=0.887a), such that third-order and fifth-order variations in the B₂, field are removed. FIG. 7D shows a plot of absolute magnetic field generated by the coil arrangement shown in FIG. 7C, similar to the plot shown in FIG. 7B. The dashed lines 801 and 802 indicate areas inside the space enclosed by the coils in which a deviation from linearity of the magnetic gradient field are respectively ≤5% and ≤0.1%.

It will be appreciated that simple circular loops are the simplest arrangement of simple discrete winding elements, and that other coil arrangements comprising other discrete winding elements (for example, straight segments, arcs, or any other discrete configuration) may be utilised to generate different magnetic fields or correct for different orders of field variations. The parameters of the specified discrete winding elements to be optimised are one or more of a spacing (for example, along a longitudinal axis of a cylindrical structure), placement and orientation in order to produce a desired magnetic field.

It will be noted that because the optimisation of the winding configurations shown in FIGS. 7A and 7C accounts for the interaction of the windings with the passive magnetic shielding material, the performance (for example, the field homogeneity) of the windings will be noticeably or measurably worse when not in the presence of passive magnetic shielding material, as described above. The field produced by a winding optimised accounting for the interactions with passive magnetic shielding material will be more similar to a desired field (e.g., the desired field the optimisation is aimed towards producing) when the winding is in the presence of passive magnetic shielding material than when the winding is not in the presence of passive magnetic shielding material.

The methods and embodiments described above in relation to a current source restricted to flow over the inner cylindrical surface of a hollow cylinder. It will be appreciated that those methods and embodiments may be adapted for planar geometries (for example, to determine the response of a hollow cylinder of high magnetic permeability to a current source on a circular plane, parallel to planar end caps of the cylinder). That may enable one or more planar current-carrying winding configurations to be used in addition to (or alternatively to) winding configurations determined using the embodiments described above. That may lead to enhanced performance of a magnetic field cancellation (or generation) system, for example extension of a cancelling field over a larger internal region of the hollow cylindrical shield, simpler manufacturing of optimal designs, further miniaturisation of magnetic field cancellation (or generation) systems, and a greater number of options for generating magnetic fields inside magnetic shielding material (e.g., a cylindrical magnetic shield).

The embodiment described below illustrates how the method described above for a current source flowing over the inner surface of a hollow cylinder may be adapted.

As described above, accurate generation of magnetic fields in the vicinity of a material of high magnetic permeability, μᵣ>>1, the boundary conditions at the surface of the material must be determined. Those conditions can be constructed through the interface conditions on the magnetic field, B, and the magnetic field strength, H. If no surface currents are present along the interface of the material with the surrounding air, the magnetic field strength tangent to the shared boundary must be continuous (as described at 1.67, where ∧ is the vector cross product). High magnetic permeability materials (for example, Mu-metal®) can have μᵣ, values ≥100000 times greater than that of air. The magnetisation of those materials adjusts to provide a response that abruptly changes the magnetic field at the boundary to satisfy 1.67. That is equivalent to stating that the magnetic field components parallel to the surface of the high magnetic permeability material, S, approximately vanish (see 1.68).

The response of high permeability magnetic materials can be modelled as perfect magnetic conductors (e.g., infinite permeability). That is because the magnetic field generated by a material of high magnetic permeability in response to an induced field deviates from that of a perfect magnetic conductor on the scale of μᵣ⁻¹ [8], [9].

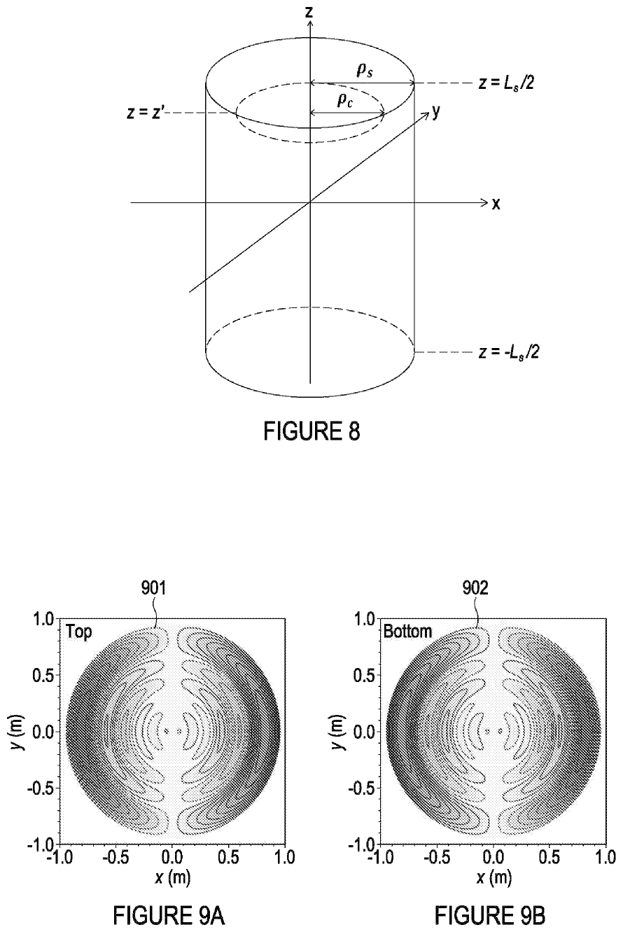

FIG. 8 shows a closed hollow cylinder of high magnetic permeability material. The cylinder has radius ρₛ, length Lₛ, and planar end caps located at z=±Lₛ/2. The cylinder is surrounded by free space. Inside the cylinder, an arbitrary current flows around a circular coil of radius ρ_{c}≤ρₛ which is centred along the z-axis and located in the z=z′ plane, where |z′|<Lₛ/2 as shown in FIG. 8. Due to the boundary conditions at the surface of the high magnetic permeability material, the magnetic field at the boundary of the cylinder is given by

$${B}_{ρ} {\vert}_{z = \pm {L}_{s} / 2} = 0 , {B}_{z} {\vert}_{ρ = {ρ}_{s}} = 0 , {B}_{ϕ} {\vert}_{z = \pm {L}_{s} / 2 , ρ = {ρ}_{s}} = 0 \qquad ( 1.132 )$$

As described above, the magnetic field generated by a closed high magnetic permeability cylinder can be expressed via an infinite set of pseudo-current densities induced on the surface of an infinite cylinder. For embodiments in which a current source is restricted to flow over an inner cylindrical surface of a hollow cylinder, that may be achieved, for example, using a cylindrical expanded Green's function [10], determining matching conditions through a Fourier decomposition of the magnetic field, allowing the radial boundary condition on the surface of the cylinder to be satisfied. A similar expansion for a planar expanded Green's function in cylindrical coordinates is now shown for embodiments in which a current source flows on a circular plane.

The components of the vector potential are expressed in cylindrical coordinates

A_{ρ}(r)=μ₀∫_{r′}d³r′G(r,r′)[J_{ρ}(r′)cos(ϕ−ϕ′)+J_{Φ}(r′)sin(ϕ−ϕ′)] (1.133)

A_{ϕ}(r)=−μ₀∫_{r′}d³r′G(r,r′)[J_{ρ}(r′)sin(ϕ−ϕ′)+J_{Φ}(r′)cos(ϕ−ϕ′)] (1.134)

A_{z}(r)=μ₀∫_{r′}d³r′G(r,r′)J_{z}(r′) (1.135)

where G(r−r′) is a Green's function satisfying Laplace's equation. The form of the vector potential can be simplified using a streamfunction representation of the current density. Since there is no current flow in the z-direction, the continuity equation can be used to represent the radial and azimuthal current densities in terms of a single scalar function

$${J}_{ρ} ( {ρ}^{′} , {ϕ}^{′} ) = \frac{1}{{ρ}^{′}} \frac{\partial S ( {ρ}^{′} , {ϕ}^{′} )}{\partial {ϕ}^{′}} , {J}_{ϕ} ( {ρ}^{′} , {ϕ}^{′} ) = - \frac{\partial S ( {ρ}^{′} , {ϕ}^{′} )}{\partial {ρ}^{′}} \qquad ( 1.136 )$$

To exploit the radial symmetries of the system the Green's function can be decomposed through the use of the Bessel function of the first kind, Jₘ(z)

$$G ( r , {r}^{′} ) = \frac{1}{4 π} {\sum }_{m = - ∞}^{∞} {e}^{im ( ϕ - {ϕ}^{′} )} {\int }_{0}^{∞} d k {e}^{- k \vert z - {z}^{′} \vert} {J}_{m} ( k ρ ) {J}_{m} ( k {ρ}^{′} ) \qquad ( 1.137 )$$

allowing the vector potential to be expressed in terms of cylindrical harmonics defined on a circular plane.

Using 1.133 to 1.135, 1.136 and 1.137, the vector potential is cast in the simplified form

$${A}_{ρ} ( r ) = \frac{i {μ}_{0}}{2 ρ} {\sum }_{m = - ∞}^{∞} {e}^{im ϕ} {\int }_{0}^{∞} {dkme}^{- k \vert z - {z}^{′} \vert} {J}_{m} ( k ρ ) {S}^{m} ( k ) \qquad ( 1.138 )$$

$${A}_{ϕ} ( r ) = - \frac{{μ}_{0}}{2} {\sum }_{m = - ∞}^{∞} {e}^{im ϕ} {\int }_{0}^{∞} d k k {e}^{- k \vert z - {z}^{′} \vert} {J}_{m} ( k ρ ) {S}^{m} ( k ) \qquad ( 1.139 )$$

$${A}_{z} ( r ) = 0 \qquad ( 1.14 )$$

where J′ₘ(z) are the derivatives of Jₘ(z) with respect to z, and S^{m}(k) is defined by the m^{th} order Henkel Transform of the stream function

$${S}^{m} ( k ) = \frac{1}{2 π} {\int }_{0}^{∞} d {ρ}^{′} {\int }_{0}^{2 π} d ϕ {e}^{- im {ϕ}^{′}} {ρ}^{′} {J}_{m} ( k {ρ}^{′} ) S ( {ρ}^{′} , {ϕ}^{′} ) \qquad ( 1.141 )$$

Through the introduction of a pseudo-current density induced on an infinite cylinder we can equate the shared azimuthal Fourier modes at the boundary (1.132) and find a Fourier representation of the pseudo-current density. Since the pseudo and planar current densities are spatially orthogonal to the planar end caps, any subsequent images generated by the application of the method of mirror images continue to satisfy the radial boundary condition. This means that they satisfy the boundary conditions in 1.68 over the entire surface of the finite closed high magnetic permeability cylinder.

Taking the curl of the vector potential (1.138 and 1.139), including the magnetic field generated by a cylindrical current source as described in the embodiment above, while also applying the method of mirror images, the total magnetic field in the region ρ<ρₛ is given by

$${B}_{ρ} ( ρ , ϕ , z ) = - \frac{{μ}_{0}}{2 π} {\sum }_{p = - ∞}^{∞} {\sum }_{m = - ∞}^{∞} {e}^{im ϕ} [ {\int }_{0}^{∞} d k {k}^{2} \frac{( z - {( - 1 )}^{p} {z}^{′} + {pL}_{s} )}{\vert z - {( - 1 )}^{p} {z}^{′} + {pL}_{s} \vert} {e}^{- k \vert z - {( - 1 )}^{p} {z}^{′} + {pL}_{s} \vert} {J}_{m}^{′} ( k ρ ) {S}^{m} ( k ) - \frac{i {ρ}_{s}}{π} {\int }_{- ∞}^{∞} d k k {e}^{i k z} {I}_{m}^{′} ( \vert k \vert ρ ) {K}_{m}^{′} ( \vert k \vert {ρ}_{s} ) {J}_{ϕ}^{m p} ( k ) ] \qquad ( 1.142 )$$

$${B}_{ϕ} ( ρ , ϕ , z ) = - \frac{i {μ}_{0}}{2 ρ} {\sum }_{p = - ∞}^{∞} {\sum }_{m = - ∞}^{∞} m {e}^{im ϕ} [ {\int }_{0}^{∞} dkk \frac{( z - {( - 1 )}^{p} {z}^{′} + {pL}_{s} )}{\vert z - {( - 1 )}^{p} {z}^{′} + {pL}_{s} \vert} {e}^{- k \vert z - {( - 1 )}^{p} {z}^{′} + {pL}_{s} \vert} {J}_{m} ( k ρ ) {S}^{m} ( k ) - \frac{i {ρ}_{s}}{π} {\int }_{- ∞}^{∞} d k \frac{\vert k \vert}{k} {e}^{i k z} {I}_{m} ( \vert k \vert ρ ) {K}_{m}^{′} ( \vert k \vert {ρ}_{s} ) {J}_{ϕ}^{m p} ( k ) ] \qquad ( 1.143 )$$

$${B}_{z} ( ρ , ϕ , z ) = \frac{{μ}_{0}}{2} {\sum }_{p = - ∞}^{∞} {\sum }_{m = - ∞}^{∞} {e}^{im ϕ} [ {\int }_{0}^{∞} d k {k}^{2} {e}^{- k \vert z - {( - 1 )}^{p} {z}^{′} + {pL}_{s} \vert} {J}_{m} ( k ρ ) {S}^{m} ( k ) - \frac{{ρ}_{s}}{π} {\int }_{- ∞}^{∞} dk \vert k \vert {e}^{i k z} {I}_{m} ( \vert k \vert ρ ) {K}_{m}^{′} ( \vert k \vert {ρ}_{s} ) {J}_{ϕ}^{m p} ( k ) ] \qquad ( 1.144 )$$

where J_{ϕ}^{mp}(k) is the p^{th} reflected Fourier transformed azimuthal pseudo-current density induced on the cylindrical surface of the magnetic shield material. Using the boundary condition (1.132) while imposing that each azimuthal Fourier mode of the magnetic field matches the azimuthal mode in both the planar streamfunction and the azimuthal pseudo-current density, the following relation is generated

$${\int }_{- ∞}^{∞} dk \vert k \vert {e}^{i k z} {I}_{m} ( \vert k \vert {ρ}_{s} ) {K}_{m}^{′} ( \vert k \vert {ρ}_{s} ) {J}_{ϕ}^{m p} ( k ) = \frac{π}{{ρ}_{s}} {\int }_{0}^{∞} d d {k}^{2} {e}^{- k \vert z - {( - 1 )}^{p} {z}^{′} + {pL}_{s} \vert} {J}_{m} ( k {ρ}_{s} ) {S}^{m} ( k ) \qquad ( 1.145 )$$

Physically, due to the formulation of the response in terms of a pseudo-current density, there must be a unique solution that satisfies the boundary condition over the infinite domain of the cylindrical shield which is independent of the axial position. Therefore, performing an inverse Fourier transform with respect to z results in the integral representation of the p^{th} reflected Fourier pseudo-current density

$${J}_{ϕ}^{m p} ( k ) = \frac{{e}^{- i k ( {( - 1 )}^{{p}_{{z}^{′} + pLs}} )}}{{ρ}_{s} \vert k \vert {I}_{m} ( \vert k \vert {ρ}_{s} ) {K}_{m}^{′} ( \vert k \vert {ρ}_{s} )} {\int }_{0}^{∞} d \tilde{k} \frac{{\tilde{k}}^{3}}{{\tilde{k}}^{2} + {k}^{2}} {J}_{m} ( \tilde{k} {ρ}_{s} ) {S}^{m} ( \tilde{k} ) \qquad ( 1.146 )$$

Having determined the magnetic field in terms of the Fourier transformed streamfunction, S^{m}(k), an appropriate expansion of the real-space streamfunction, S(ρ′,ϕ′), must be chosen. Although the choice of orthogonal basis for the streamfunction expansion is arbitrary, a choice of basis which considers the symmetries and nature of a Hankel Transform will yield a solution that is greatly simplified. On a circular plane, a Fourier-Bessel series representation of the radial component of the streamfunction may be chosen, while using the Fourier series representation for the azimuthal dependence

$$S ( {ρ}^{′} , {ϕ}^{′} ) = ( H ( {ρ}^{′} ) - H ( ρ - {ρ}_{c} ) ) {ρ}_{c} {\sum }_{n = 1}^{N} {\sum }_{{m}^{′} = 0}^{M} {J}_{{m}^{′}} ( \frac{{ρ}_{n {m}^{′}} {ρ}^{′}}{{ρ}_{c}} ) ( {W}_{n {m}^{′}} cos ( {m}^{′} {ϕ}^{′} ) + {Q}_{n {m}^{′}} sin ( {m}^{′} {ϕ}^{′} ) ) \qquad ( 1.147 )$$

where (W_{nm′}, Q_{nm′}) are Fourier coefficients and ρ_{nm′} is the n^{th} zero of the m^{th} Bessel function of the first kind, J_{m′}(ρ_{nm′})=0. The total magnetic field generated by an arbitrary current flow on the surface of a circular coil inside a closed finite cylinder of high magnetic permeability is thus given by

$${B}_{ρ} ( r ) = \frac{{μ}_{0} {ρ}_{c}^{3}}{2} {\sum }_{n = 1}^{N} {\sum }_{m = 0}^{M} {ρ}_{n m} {J}_{m}^{′} ( {ρ}_{n m} ) ( {W}_{n m} cos ( m ϕ ) + {Q}_{n m} sin ( m ϕ ) ) {B}_{ρ}^{n m} ( ρ , z ) \qquad ( 1.148 )$$

$${B}_{ϕ} ( r ) = \frac{{μ}_{0} {ρ}_{c}^{3}}{2 ρ} {\sum }_{n = 1}^{N} {\sum }_{m = 0}^{M} m {ρ}_{n m} {J}_{m}^{′} ( {ρ}_{n m} ) ( {W}_{n m} sin ( m ϕ ) - {Q}_{n m} cos ( m ϕ ) ) {B}_{ϕ}^{n m} ( ρ , z ) \qquad ( 1.149 )$$

$${B}_{z} ( r ) = \frac{{μ}_{0} {ρ}_{c}^{3}}{2} {\sum }_{n = 1}^{N} {\sum }_{m = 0}^{M} {ρ}_{n m} {J}_{m}^{′} ( {ρ}_{n m} ) ( {W}_{n m} cos ( m ϕ ) + {Q}_{n m} sin ( m ϕ ) ) {B}_{z}^{n m} ( ρ , z ) where \qquad ( 1.15 )$$

$${B}_{ρ}^{n m} ( ρ , z ) = - {\int }_{0}^{∞} d k {k}^{2} σ ( k ; z , {z}^{′} , {L}_{s} ) \frac{{J}_{m}^{′} ( k ρ ) {J}_{m} ( k {ρ}_{c} )}{{k}^{2} {ρ}_{c}^{2} - {ρ}_{n m}^{2}} - {\sum }_{p = 1}^{∞} \tilde{p} \vert \tilde{p} \vert {λ}_{p} ( z , {z}^{′} , {L}_{s} ) \frac{{I}_{m}^{′} ( \vert \tilde{p} \vert ρ ) {I}_{m} ( \vert \tilde{p} \vert {ρ}_{c} ) {K}_{m} ( \vert \tilde{p} \vert {ρ}_{s} )}{{I}_{m} ( \vert \tilde{p} \vert {ρ}_{s} ) ( {\vert \tilde{p} \vert}^{2} {ρ}_{c}^{2} + {ρ}_{n m}^{2} )} \qquad ( 1. 151 )$$

$${B}_{ϕ}^{n m} ( ρ , z ) = {\int }_{0}^{∞} d k k σ ( k ; z , {z}^{′} , {L}_{s} ) \frac{{J}_{m} ( k ρ ) {J}_{m} ( k {ρ}_{c} )}{{k}^{2} {ρ}_{c}^{2} - {ρ}_{n m}^{2}} + {\sum }_{p = 1}^{∞} \tilde{p} {λ}_{p} ( z , {z}^{′} , {L}_{s} ) \frac{{I}_{m} ( \vert \tilde{p} \vert ρ ) {I}_{m} ( \vert \tilde{p} \vert {ρ}_{c} ) {K}_{m} ( \vert \tilde{p} \vert {ρ}_{s} )}{{I}_{m} ( \vert \tilde{p} \vert {ρ}_{s} ) ( {\vert \tilde{p} \vert}^{2} {ρ}_{c}^{2} + {ρ}_{n m}^{2} )} \qquad ( 1.152 )$$

$${B}_{z}^{n m} ( ρ , z ) = {\int }_{0}^{∞} d k {k}^{2} γ ( k ; z , {z}^{′} , {L}_{s} ) \frac{{J}_{m} ( k ρ ) {J}_{m} ( k {ρ}_{c} )}{{k}^{2} {ρ}_{c}^{2} - {ρ}_{n m}^{2}} - {\sum }_{p = 1}^{∞} {\tilde{p}}^{2} {τ}_{p} ( z , {z}^{′} , {L}_{s} ) \frac{{I}_{m} ( \vert \tilde{p} \vert ρ ) {I}_{m} ( \vert \tilde{p} \vert {ρ}_{c} ) {K}_{m} ( \vert \tilde{p} \vert {ρ}_{s} )}{{I}_{m} ( \vert \tilde{p} \vert {ρ}_{s} ) ( {\vert \tilde{p} \vert}^{2} {ρ}_{c}^{2} + {ρ}_{n m}^{2} )} and \qquad ( 1.153 )$$

$$γ ( k ; z , {z}^{′} , {L}_{s} ) = {e}^{- k \vert z - {z}^{′} \vert} + \frac{2}{{e}^{2 k {L}_{s} - 1}} [ {e}^{k {L}_{s}} cosh ( k ( z + {z}^{′} ) ) + cosh ( k ( z - {z}^{′} ) ) ] \qquad ( 1.154 )$$

$$σ ( k ; z , {z}^{′} , {L}_{s} ) = \frac{( z - {z}^{′} )}{\vert z - {z}^{′} \vert} {e}^{- k \vert z - {z}^{′} \vert} - \frac{2}{{e}^{2 k {L}_{s} - 1}} [ {e}^{k {L}_{s}} sinh ( k ( z + {z}^{′} ) ) + sinh ( k ( z - {z}^{′} ) ) ] \qquad ( 1.155 )$$

$${λ}_{p} ( z , {z}^{′} , {L}_{s} ) = \frac{2}{{L}_{s}} ( {( - 1 )}^{p} sin ( \tilde{p} ( z + {z}^{′} ) ) + sin ( \tilde{p} ( z - {z}^{′} ) ) ) \qquad ( 1.156 )$$

$${τ}_{p} ( z , {z}^{′} , {L}_{s} ) = \frac{2}{{L}_{s}} ( {( - 1 )}^{p} cos ( \tilde{p} ( z + {z}^{′} ) ) + cos ( \tilde{p} ( z - {z}^{′} ) ) ) \qquad ( 1.157 )$$

with \tilde{p}=pπ/Lₛ. A derivation of the above is provided in Appendix A. Solving for the unknown Fourier coefficients, (W_{nm′},Q_{nm′}), in the system of governing equations (1.148 to 1.150) is an ill-conditioned problem due to the formulation of the vector potential via the integral representation in 1.133 to 1.135. That may be solved using an optimisation process such as a least squares minimisation [11], with the addition of a penalty term which acts as a regularisation parameter [12]. The regularisation term may take many forms, with individual terms in it representing, for example: the curvature of a given wire geometry, the energy stored, the power dissipated etc. The choice, however, is somewhat arbitrary as any regularisation parameters acts to facilitate inversion. If the regularisation term is large, then the inverse problem is well-conditioned and yields a more simplistic coil design which compromises field fidelity. On the other hand, if the regularisation term is small, then the result is a less well-conditioned inverse problem, a more intricate coil design, and higher field fidelity. For example, using the power dissipated by the coil as a regularisation term, the power dissipated by a circular coil of thickness, t, and resistivity, [symbol] , is given by

$$P = \frac{t}{} {\int }_{0}^{{ρ}_{c}} d {ρ}^{′} {ρ}^{′} {\int }_{0}^{2 π} d {ϕ}^{′} + {\vert {J}_{p} ( {ρ}^{′} , {ϕ}^{′} ) \vert}^{2} + {\vert {J}_{ϕ} ( {ρ}^{′} , {ϕ}^{′} ) \vert}^{2} \qquad ( 1.158 )$$

Using 1.136, 1.147 and 1.158 and integrating over the planar surface, the power can be related to the unknown Fourier coefficients. For m=0 it can be found that

$$P = \frac{t}{} π {ρ}_{c}^{2} {\sum }_{n = 1}^{N} {W}_{n 0}^{2} {ρ}_{n 0}^{2} {{J}_{1} ( {ρ}_{n 0} )}^{2} \qquad ( 1.159 )$$

and for mϵ [symbol] ⁺ it can be found that

$$P = \frac{t}{} π {ρ}_{c}^{2} {\sum }_{n = 1}^{N} {\sum }_{m = 1}^{M} ( {W}_{n m}^{2} + {Q}_{n m}^{2} ) {( \frac{{ρ}_{n m}}{2} )}^{2 m} \frac{1}{m ! ( m - 1 ) !} [ \text{} {}_{2} {\tilde{F}}_{3} ( m , m + \frac{1}{2} ; m + 1 , m + 1 , 2 m + 1 ; - {ρ}_{n m}^{2} ) - \frac{{ρ}_{n m}^{2}}{2 {( m + 1 )}^{2}} {}_{3} {\tilde{F}}_{4} ( m + \frac{1}{2} , m + 1 , m + 1 ; m , m + 2 , m + 2 , 2 m + 1 ; - {ρ}_{n m}^{2} ) ] \qquad ( 1.16 )$$

where ᵢ\tilde{F}ⱼ is the regularised hypergeometric function (see Appendix B for more details). A cost function can now be formulated

Φ=αΣₖ₌₁^{K}[B^{desired}(rₖ)−B(rₖ)]²+βP (1.161)

where α and β are weighting parameters chosen such that the physical parameters, such as total power, may be adjusted to fit the desired field fidelity. The cost function may be minimised, for example using the method of least squares, to calculate the optimal Fourier coefficients (W_{nm′}, Q_{nm′}) to generate a target magnetic field at K target field points. The minimisation is achieved by taking the differential of the functional with respect to the Fourier coefficients,

$$\frac{\partial Φ}{\partial {W}_{i j}} = 0 , \frac{\partial Φ}{\partial {Q}_{i j}} = 0 , i > 1 , j > 0 \qquad ( 1.162 )$$

allowing the optimal Fourier coefficients to be found for any given physical target magnetic field profile through matrix inversion. The inversion process yields the optimal continuous streamfunction defined on the surface where current flow is permitted. The final objective, however, is to design a coil which generates the desired magnetic field to a specified accuracy. To do that, a discrete approximation to the current continuum may be found by contouring the stream function into Nₛ values to find the streams lines (e.g., contours of the streamfunction) where a winding should be laid to generate the desired target magnetic field.

In summary, a Green's function formulation is used to determine the magnetic field generated by an arbitrary planar current source. That may be achieved by decomposing the magnetic field into azimuthal Fourier modes. The magnetisation of the high magnetic permeability cylinder is then represented by an equivalent pseudo-current density induced on an infinite cylinder. The corresponding magnetic field is then decomposed into the same azimuthal Fourier modes. The magnetic fields generated by both the planar current source and the high magnetic permeability cylinder are then matched at the radial boundary of the high magnetic permeability cylinder (by exploiting the shared azimuthal symmetries). That may enable the pseudo-current on the cylinder to be related to the static current source on the plane. Since the planar end caps are substantially parallel to one another, and substantially perpendicular to the pseudo-current density induced on the infinite cylinder, the boundary conditions on the planar ends caps and on the cylindrical body of the high magnetic permeability material can be satisfied simultaneously (for example, using the method of mirror images).

It will be appreciated that the general framework of the method described above for embodiments in which current flow is restricted to an inner cylindrical surface of a hollow cylinder may be followed for embodiments in which current flow is restricted to inner planar surfaces of the hollow cylinder, but in formulating the magnetic field generated by the planar current source, a Green's function with symmetries akin to the Fourier modes of planar geometries is used. The coupling of the planar coil to a high magnetic permeability shield is treated in a substantially identical manner in both embodiments.

Application of the methodology described above for embodiments in which current flow is restricted to planar surfaces is discussed below. The optimised generation of a uniform magnetic field, Bₓ, between, and normal to, two planar coils inside a closed cylindrical magnetic shield is considered. The analytical model was verified through comparison with numerical simulations made used FEM software (COMSOL Multiphysics® Version 5.3a).

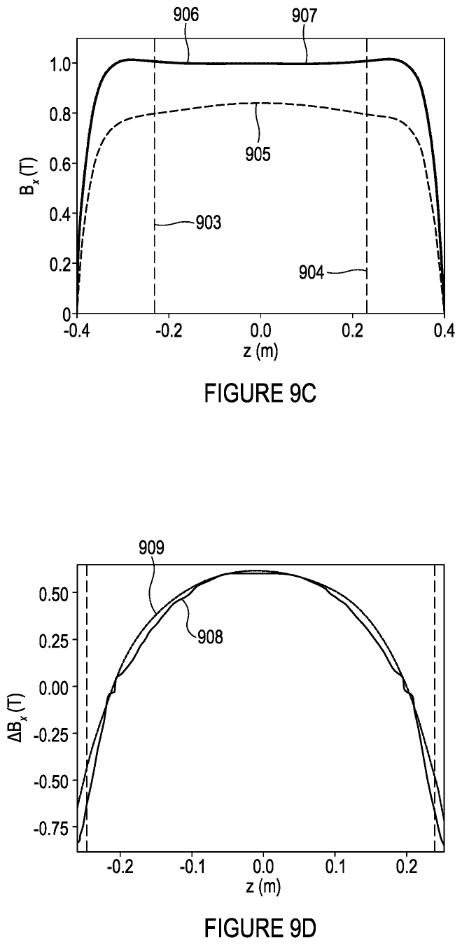

To generate Bₓ, first the optimal continuum currents on two circular plats which minimise the cost function were determined. Planar windings 901, 902 of radius ρ_{c}=0.95 m were located in top and bottom planes z′=±0.475 m and placed symmetrically inside a closed high magnetic permeability cylinder of length Lₛ=1 m and radius ρₛ=1m. The current continuum was generated using 800 Fourier coefficients (N=200 and M=1) on each plane (see FIGS. 9A and 9B showing the top plate and bottom plate respectively). The magnetic field was optimised between ρ=±ρ_{c}/2 and z=±z′/2 (shown by the dashed black lines 903, 904 in FIGS. 9C and 9D). to generate a constant target field, Bₓ, in the x-direction perpendicular to the planes. The colour map in FIGS. 9A and 9B represents the optimal current continuum solutions on the top (FIG. 9A) and bottom (FIG. 9B) planes, showing the magnitude of the stream function (where blue represents a low value, and red represents a high value). Solid and dashed black lines represent discrete wires with opposite sense of current flow which approximate the current continuum.

The magnetic field generated by the two plates is shown in FIG. 9C. The magnetic field Bₓ, generated by the windings 901, 902 only (i.e., without the high magnetic permeability cylinder present) is shown by the green dashed line 905 in FIG. 9C, and is calculated using the Biot-Savart Law taking Nₛ=100. The magnetic field Bₓ generated in the presence of the high magnetic permeability cylinder is calculated as a function of axial position z from the current continuum plots in FIGS. 9A and 9B both analytically (solid red line 906) and numerically using FEM software (dotted blue line 907) are shown in FIG. 9C. FIG. 9D shows the magnetic field deviation ΔBₓ=Bₓ−Bₓ^{desired} of the field profiles shown in FIG. 9C, as calculated both analytically (solid red line 908) and numerically (dotted blue line 909).

It can be seen from that the magnetic field generated by the two plates in the presence of the high magnetic permeability cylinder is highly homogeneous. The maximum field deviation max(ΔB) was only 0.62% over a length of 50 cm across the optimised region, when calculated using the set of equations 1.148 to 1.150 and 0.60% when calculated numerically taking the high magnetic permeability cylinder parameters to be μᵣ=20000 and thickness d=1mm. The green dashed line 905 indicates that the magnetic field Bₓ, generated by the windings 901, 902 is measurably worse when the windings 901, 902 are not in the presence of the high magnetic permeability cylinder, similar to the windings 601, 602 described above.

From reading the present disclosure, other variations and modifications will be apparent to the skilled person. Such variations and modifications may involve equivalent and other features which are already known in the art of magnetic shielding technology, and which may be used instead of, or in addition to, features already described herein.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable sub-combination. The applicant hereby gives notice that new claims may be formulated to such features and/or combinations of such features during the prosecution of the present application or of any further application derived therefrom.

For the sake of completeness, it is also stated that the term “comprising” does not exclude other elements or steps, the term “a” or “an” does not exclude a plurality, a single processor or other unit may fulfil the functions of several means recited in the claims and any reference signs in the claims shall not be construed as limiting the scope of the claims.

### APPENDIX A

In order to derive the magnetic field in terms of the streamfunction, first both the Fourier transform of the streamfunction and the induced Fourier pseudo-current density must be determined. Substituting 1.147 into 1.141 and integrating over the azimuthal coordinate yields

$${S}^{m} ( k ) = \frac{{ρ}_{c}}{2} {\sum }_{n = 1}^{N} {\sum }_{{m}^{′} = 0}^{M} ( {W}_{{nm}^{′}} ( {δ}_{{mm}^{′}} + {δ}_{m , - {m}^{′}} ) + i {Q}_{{nm}^{′}} ( {δ}_{{mm}^{′}} - {δ}_{m , - {m}^{′}} ) ) \times {\int }_{0}^{{ρ}_{c}} d {ρ}^{′} {ρ}^{′} {J}_{m} ( k {ρ}^{′} ) {J}_{{m}^{′}} ( \frac{{ρ}_{{nm}^{′}} ρ′}{{ρ}_{c}} ) \qquad ( 2.1 )$$

Upon substituting 2.1 into the magnetic field 1.132 to 1.134 the delta functions collapse the infinite summation, resulting in every Bessel function of order m being replaced by m′. Hence, without loss of generality, using the Bessel function product identity found in [12], the following may be written

$${S}^{m} ( k ) = \frac{{ρ}_{c}^{3}}{2} {\sum }_{n = 1}^{N} {\sum }_{{m}^{′} = 0}^{M} ( {W}_{{nm}^{′}} ( {δ}_{{mm}^{′}} + {δ}_{m , - {m}^{′}} ) + i {Q}_{{nm}^{′}} ( {δ}_{{mm}^{′}} - {δ}_{m , - {m}^{′}} ) ) \times \frac{{ρ}_{{nm}^{′}}}{{k}^{2} {ρ}_{c}^{2} - {ρ}_{{nm}^{′}}^{2}} {J}_{{m}^{′}} ( k {ρ}_{c} ) {J}_{{m}^{′}}^{′} ( {ρ}_{{nm}^{′}} ) \qquad ( 2.2 )$$

Similarly, the induced Fourier pseudo-current density may be now be calculated. Substituting 1.147 into 1.146 and integrating over the azimuthal coordinate yields

$${J}_{ϕ}^{m p} ( k ) = \frac{{ρ}_{c} {e}^{- i k ( {( - 1 )}^{p} {z}^{′} + {pL}_{s} )}}{2 {ρ}_{s} \vert k \vert {I}_{m} ( \vert k \vert {ρ}_{s} ) {K}_{m}^{′} ( \vert k \vert {ρ}_{s} )} {\sum }_{n = 1}^{N} {\sum }_{{m}^{′} = 0}^{M} ( {W}_{{nm}^{′}} ( {δ}_{{mm}^{′}} + {δ}_{m , - {m}^{′}} ) + {iQ}_{{nm}^{′}} ( {δ}_{{mm}^{′}} - {δ}_{m , - {m}^{′}} ) ) \times {\int }_{0}^{∞} d \tilde{k} \frac{{\tilde{k}}^{3}}{{\tilde{k}}^{2} + {k}^{2}} {J}_{m} ( \tilde{k} {ρ}_{s} ) {\int }_{0}^{{ρ}_{c}} d {ρ}^{′} {ρ}^{′} {J}_{{m}^{′}} ( \tilde{k} {ρ}^{′} ) {J}_{{m}^{′}} ( \frac{{ρ}_{{nm}^{′}} {ρ}^{′}}{{ρ}_{c}} ) \qquad ( 2.3 )$$

First the integral over \tilde{k} is considered. Separating this using partial fractions yields

$${\int }_{0}^{∞} d \tilde{k} \frac{{\tilde{k}}^{3}}{{\tilde{k}}^{2} + {k}^{2}} {J}_{m} ( \tilde{k} {ρ}_{s} ) {J}_{m} ( \tilde{k} {ρ}^{′} ) = {\int }_{0}^{∞} d \tilde{k} \tilde{k} {J}_{m} ( \tilde{k} {ρ}_{s} ) {J}_{m} ( \tilde{k} {ρ}^{′} ) - {k}^{2} {\int }_{0}^{∞} d \tilde{k} \frac{\tilde{k}}{{\tilde{k}}^{2} + {k}^{2}} {J}_{m} ( \tilde{k} {ρ}_{s} ) {J}_{m} ( \tilde{k} {ρ}^{′} ) \qquad ( 2.4 )$$

The first integral is the orthogonality relation between Bessel functions, and the second can be found in [11]. It can therefore be stated that

$${\int }_{0}^{∞} d \tilde{k} \frac{{\tilde{k}}^{3}}{{\tilde{k}}^{2} + {k}^{2}} {J}_{m} ( \tilde{k} {ρ}_{s} ) {J}_{m} ( \tilde{k} {ρ}^{′} ) = \frac{δ ( {ρ}^{′} - {ρ}_{s} )}{{ρ}^{′}} - {k}^{2} {I}_{{m}^{′}} ( \vert k \vert {ρ}^{′} ) {K}_{{m}^{′}} ( \vert k \vert {ρ}_{s} ) \qquad ( 2.5 )$$

Integrating 2.5 into 2.3 and integrating over ρ′ using the same identity as in 2.2 results in the expression

$${J}_{ϕ}^{m p} = \frac{{ρ}_{c} {k}^{2} {e}^{- i k ( {( - 1 )}^{p} {z}^{′} + pLs )}}{2 {ρ}_{s} \vert k \vert {I}_{m} ( \vert k \vert {ρ}_{s} ) {K}_{m}^{′} ( \vert k \vert {ρ}_{s} )} {\sum }_{n = 1}^{N} {\sum }_{{m}^{′} = 0}^{M} ( {W}_{{nm}^{′}} ( {δ}_{{mm}^{′}} + {δ}_{m , - {m}^{′}} ) + i {Q}_{{nm}^{′}} ( {δ}_{{mm}^{′}} - {δ}_{m , - {m}^{′}} ) ) \times \frac{{ρ}_{{nm}^{′}}}{{k}^{2} {ρ}_{c}^{2} + {ρ}_{{nm}^{′}}^{2}} {J}_{{m}^{′}}^{′} ( {ρ}_{{nm}^{′}} ) {I}_{{m}^{′}} ( \vert k \vert {ρ}_{c} ) {K}_{{m}^{′}} ( \vert k \vert {ρ}_{s} ) \qquad ( 2.6 )$$

Substituting 2.2 and 2.6 into 1.142 to 1.144 allows the expression of the summation over exponentials associated with the infinite reflections of the planar streamfunction as

$${\sum }_{p = - ∞}^{∞} {e}^{- k \vert z - {( - 1 )}^{p} {z}^{′} + {pL}_{s} \vert} = {e}^{- k \vert z - {z}^{′} \vert} + \frac{2}{{e}^{2 k L} - 1} ( {e}^{k L} cosh ( k ( z + {z}^{′} ) ) + cosh ( k ( z - {z}^{′} ) ) ) \qquad ( 2.7 )$$

$$and$$

$${\sum }_{p = - ∞}^{∞} \frac{( z - {( - 1 )}^{p} {z}^{′} + {pL}_{s} )}{\vert z - {( - 1 )}^{p} {z}^{′} + {pL}_{s} \vert} {e}^{- k \vert z - {( - 1 )}^{p} {z}^{′} + {pL}_{s} \vert} = \frac{( z - {z}^{′} )}{\vert z - {z}^{′} \vert} {e}^{- k \vert z - {z}^{′} \vert} - \frac{2}{{e}^{2 k L} - 1} ( {e}^{k L} sinh ( k ( z + {z}^{′} ) ) + sinh ( k ( z - {z}^{′} ) ) ) \qquad ( 2.8 )$$

while expressing the summation over the infinite pseudo-current reflections through a Fourier series expansion

$${\sum }_{p = - ∞}^{∞} {e}^{i k ( z - {( - 1 )}^{p} {z}^{′} + {pL}_{s} )} = \frac{π}{L} {\sum }_{p = - ∞}^{∞} δ ( k - \frac{p π}{L} ) ( {e}^{i k ( z + {z}^{′} - L )} + {e}^{i k ( z - {z}^{′} )} ) \qquad ( 2.9 )$$

It may finally be written

$${B}_{ρ} ( r ) = \frac{{μ}_{0} {ρ}_{c}^{3}}{2 ρ} {\sum }_{n = 1}^{N} {\sum }_{m = 0}^{M} {ρ}_{n m} {J}_{m}^{′} ( {ρ}_{n m} ) ( {W}_{n m} cos ( m ϕ ) + {Q}_{n m} sin ( m ϕ ) ) {B}_{ρ}^{n m} ( ρ , z ) \qquad ( 2.1 )$$

$${B}_{ϕ} ( r ) = \frac{{μ}_{0} {ρ}_{c}^{3}}{2 ρ} {\sum }_{n = 1}^{N} {\sum }_{m = 0}^{M} m {ρ}_{n m} {J}_{m}^{′} ( {ρ}_{n m} ) ( {W}_{n m} sin ( m ϕ ) - {Q}_{n m} cos ( m ϕ ) ) {B}_{ϕ}^{n m} ( ρ , z ) \qquad ( 2.11 )$$

$${B}_{z} ( r ) = \frac{{μ}_{0} {ρ}_{c}^{3}}{2} {\sum }_{n = 1}^{N} {\sum }_{m = 0}^{M} {ρ}_{n m} {J}_{m}^{′} ( {ρ}_{n m} ) ( {W}_{n m} cos ( m ϕ ) + {Q}_{n m} sin ( m ϕ ) ) {B}_{z}^{n m} ( ρ , z ) \qquad ( 2.12 )$$

$$where$$

$${B}_{ρ}^{n m} ( ρ , z ) = - {\int }_{0}^{∞} d k {k}^{2} σ ( k ; z , {z}^{′} , {L}_{s} ) \frac{{J}_{m}^{′} ( k ρ ) {J}_{m} ( k {ρ}_{c} )}{{k}^{2} {ρ}_{c}^{2} - {ρ}_{n m}^{2}} - {\sum }_{p = 1}^{∞} \tilde{p} \vert \tilde{p} \vert {λ}_{p} ( z , {z}^{′} , {L}_{S} ) \frac{{I}_{m}^{′} ( \vert \tilde{p} \vert ρ ) {I}_{m} ( \vert \tilde{p} \vert {ρ}_{c} ) {K}_{m} ( \vert \tilde{p} \vert {ρ}_{s} )}{{I}_{m} ( \vert \tilde{p} \vert {ρ}_{s} ) ( {\vert \tilde{p} \vert}^{2} {ρ}_{c}^{2} + {ρ}_{n m}^{2} )} \qquad ( 2.13 )$$

$${B}_{ϕ}^{n m} ( ρ , z ) = {\int }_{0}^{∞} d k k σ ( k ; z , {z}^{′} , {L}_{s} ) \frac{{J}_{m} ( k ρ ) {J}_{m} ( k {ρ}_{c} )}{{k}^{2} {ρ}_{c}^{2} - {ρ}_{n m}^{2}} + {\sum }_{p = 1}^{∞} \tilde{p} {λ}_{p} ( z , {z}^{′} , {L}_{s} ) \frac{{I}_{m} ( \vert \tilde{p} \vert ρ ) {I}_{m} ( \vert \tilde{p} \vert {ρ}_{c} ) {K}_{m} ( \vert \tilde{p} \vert {ρ}_{s} )}{{I}_{m} ( \vert \tilde{p} \vert {ρ}_{s} ) ( {\vert \tilde{p} \vert}^{2} {ρ}_{c}^{2} + {ρ}_{n m}^{2} )} \qquad ( 2.14 )$$

$${B}_{z}^{n m} ( ρ , z ) = {\int }_{0}^{∞} d k {k}^{2} γ ( k ; z , {z}^{′} , {L}_{s} ) \frac{{J}_{m} ( k ρ ) {J}_{m} ( k {ρ}_{c} )}{{k}^{2} {ρ}_{c}^{2} - {ρ}_{n m}^{2}} - {\sum }_{p = 1}^{∞} {\tilde{p}}^{2} {τ}_{p} ( z , {z}^{′} , {L}_{s} ) \frac{{I}_{m} ( \vert \tilde{p} \vert ρ ) {I}_{m} ( \vert \tilde{p} \vert {ρ}_{c} ) {K}_{m} ( \vert \tilde{p} \vert {ρ}_{s} )}{{I}_{m} ( \vert \tilde{p} \vert {ρ}_{s} ) ( {\vert \tilde{p} \vert}^{2} {ρ}_{c}^{2} + {ρ}_{n m}^{2} )} \qquad ( 2.15 )$$

$$where$$

$$γ ( k ; z , {z}^{′} , {L}_{s} ) = {e}^{- k \vert z - {z}^{′} \vert} + \frac{2}{{e}^{2 k {L}_{s}} - 1} [ {e}^{k {L}_{s}} cosh ( k ( z + {z}^{′} ) ) + cosh ( k ( z - {z}^{′} ) ) ] \qquad ( 2.16 )$$

$$σ ( k ; z , {z}^{′} , {L}_{s} ) = \frac{( z - {z}^{′} )}{\vert z - {z}^{′} \vert} {e}^{- k \vert z - {z}^{′} \vert} - \frac{2}{{e}^{2 k {L}_{s}} - 1} [ {e}^{k {L}_{s}} sinh ( k ( z + {z}^{′} ) ) + sinh ( k ( z - {z}^{′} ) ) ] \qquad ( 2.17 )$$

$${λ}_{p} ( z , {z}^{′} , {L}_{s} ) = \frac{2}{{L}_{s}} ( {( - 1 )}^{p} sin ( \tilde{p} ( z + {z}^{′} ) ) + sin ( \tilde{p} ( z - {z}^{′} ) ) ) \qquad ( 2.18 )$$

$${τ}_{p} ( z , {z}^{′} , {L}_{s} ) = \frac{2}{{L}_{s}} ( {( - 1 )}^{p} cos ( \tilde{p} ( z + {z}^{′} ) ) + cos ( \tilde{p} ( z - {z}^{′} ) ) ) \qquad ( 2.19 )$$

$$and \tilde{p} = p π / {L}_{s} .$$

### APPENDIX B

The power dissipated in the surface of a coil of thickness, t, and resistivity, [symbol] , is given by

$$P = \frac{r}{} {\int }_{0}^{{ρ}_{c}} d {ρ}^{′} {ρ}^{′} {\int }_{0}^{2 π} d {ϕ}^{′} {\vert {J}_{ρ} ( {ρ}^{′} , {ϕ}^{′} ) \vert}^{2} + {\vert {J}_{ϕ} ( {ρ}^{′} , {ϕ}^{′} \vert}^{2} \qquad ( 2.2 )$$

Substituting the streamfunction 1.147 into the continuity relations 1.136 it is found that

$${J}_{ρ} ( {ρ}^{′} , {ϕ}^{′} ) = ( H ( {ρ}^{′} - {ρ}_{c} ) - H ( {ρ}^{′} ) ) \frac{{ρ}_{c}}{{ρ}^{′}} {\sum }_{n = 1}^{N} {\sum }_{m = 0}^{M} m {J}_{m} ( \frac{{ρ}_{n m} {ρ}^{′}}{{ρ}_{c}} ) ( {W}_{n m} sin ( m {ϕ}^{′} ) - {Q}_{n m} cos ( m {ϕ}^{′} ) ) \qquad ( 2.21 )$$

$${J}_{ϕ} ( {ρ}^{′} , {ϕ}^{′} ) = ( H ( {ρ}^{′} - {ρ}_{c} ) - H ( {ρ}^{′} ) ) {\sum }_{n = 1}^{N} {\sum }_{m = 0}^{M} {ρ}_{n n} {J}_{m}^{′} ( \frac{{ρ}_{n m} {ρ}^{′}}{{ρ}_{c}} ) ( {W}_{n m} cos ( m {ϕ}^{′} ) + {Q}_{n m} sin ( m {ϕ}^{′} ) ) \qquad ( 2.22 ) )$$

Inserting 2.21 and 2.22 into 2.20 and integrating over the azimuthal component results in

$$P = \frac{r}{} π {ρ}_{c}^{2} {\sum }_{n = 1}^{N} {\sum }_{m = 0}^{M} [ ( 1 + {δ}_{m 0} ) {W}_{n m}^{2} + ( 1 - {δ}_{m 0} ) {Q}_{n m}^{2} ] \times {\int }_{0}^{1} d \tilde{ρ} [ \frac{2 {m}^{2}}{\tilde{ρ}} {{J}_{m} ( {ρ}_{n m} \tilde{ρ} )}^{2} - {ρ}_{n m}^{2} \tilde{ρ} {J}_{m - 1} ( {ρ}_{n m} \tilde{ρ} ) {J}_{m + 1} ( {ρ}_{n m} \tilde{ρ} ) ] \qquad ( 2.23 )$$

for m∈ [symbol] ⁺, where ᵢ\tilde{F}ⱼ is the regularised hypergeometric function. Some specific evaluations of 2.23 are now presented:

$$\begin{matrix}m = 1 & P = \frac{2 t}{} π {ρ}_{c}^{2} {\sum }_{n = 1}^{N} ( {W}_{n 1}^{2} + {Q}_{n 1}^{2} ) {ρ}_{n 1}^{2} {{J}_{0} ( {ρ}_{n 1} )}^{2}\end{matrix} \qquad ( 2.24 )$$

$$m = 2 P = \frac{2 t}{} π {ρ}_{c}^{2} {\sum }_{n = 1}^{N} ( {W}_{n 2}^{2} + {Q}_{n 2}^{2} ) \\ [ ( {ρ}_{n 2}^{2} - 4 ) {{J}_{0} ( {ρ}_{n 2} )}^{2} - \frac{2 ( {ρ}_{n 2}^{2} - 8 )}{{ρ}_{n 2}} {J}_{0} ( {ρ}_{n 2} ) {J}_{1} ( {ρ}_{n 2} ) + \frac{( {ρ}_{n 2}^{4} - 16 )}{{ρ}_{n 2}^{2}} {J}_{1} {( {ρ}_{n 2} )}^{2} ] \qquad ( 2.25 )$$

$$m = 3 P = \frac{2 t}{} π {ρ}_{c}^{2} {\sum }_{n = 1}^{N} ( {W}_{n 3}^{2} + {Q}_{n 3}^{2} ) [ \frac{( {ρ}_{n 3}^{4} - 96 )}{{ρ}_{n 3}^{2}} {{J}_{0} ( {ρ}_{n 3} )}^{2} - \frac{48 ( {ρ}_{n 3}^{2} - 8 )}{{ρ}_{n 3}^{3}} {J}_{0} ( {ρ}_{n 3} ) {J}_{1} ( {ρ}_{n 3} ) + \frac{( {ρ}_{n 3}^{6} - 10 {ρ}_{n 3}^{4} + 96 {ρ}_{n 3}^{2} - 384 )}{{ρ}_{n 3}^{4}} {{J}_{1} ( {ρ}_{n 3} )}^{2} ] \qquad ( 2.26 )$$

### REFERENCES

[1] Elena Boto et al. Moving magnetoencephalography towards real-world applications with a wearable system Nature, 555 (657-661), 2018
[2] J. D. Jackson Classical Electrodynamics (3^{rd} ed.) Wiley, New York, 1998
[3] R. Turner and R. M. Bowley Passive screening of switched magnetic field gradients Journal of Physics E: Scientific Instruments, 19(876), 1986
[4] R. Turner A target field approach to optimal coil design Journal of Physics: Applied Physics, 19(8), 1986
[5] K. W. Rigby Design of magnets inside cylindrical superconductive shields Review of Scientific Instruments, 59(156), 1988
[6] C. P. Bidinosti, J. W. Martin Passive magnetic shielding in static gradient fields AIP Advances 4(047135), 2014
[7] C.-Y. Liu, Y. Andalib, D. C. M. Ostapchuk, C. P. Bidinosti Analytic models of magnetically enclosed spherical and solenoidal coils 2019
[8] P. Hammond Electric and magnetic images Proceedings of the IEE—Part C: Monographs, 107:306, 1960
[9] P. Hammond Effect of finite thickness of magnetic substrate on planar inductors IEEE Transactions on

Magnetics, 26:270-275, 1990
[10] L.-W. Li, M.-S. Leong, T.-S. Yeo, and P.-S. Kooi Electromagnetic dyadic green 's functions in spectral domain for multi-layered cylinders Journal of Electromagnetic Waves and Applications, 14:961-985, 2000
[11] Otto Bretscher Linear Algebra with Applications Pearson, London, 4 edition, 2009
[12] I. S. Gradshteyn and I. M. Ryzhik Table of Integrals, Series, and Products. Elsevier/Academic Press, Amsterdam, seventh edition, 2007. Translated from the Russian, Translation edited and with a preface by

Alan Jeffrey and Daniel Zwillinger

1. A method of designing a magnetic shield comprising a structure enclosing a space, the structure comprising passive magnetic shielding material, and a winding configured to produce a specified magnetic field within the structure when current is passed through the winding, the method comprising:
determining an optimised configuration of the winding accounting for the presence of the passive magnetic shielding material by implementing one or more boundary conditions at the surface of the passive magnetic shielding material.

2. The method of claim 1, wherein the one or more boundary conditions require that the magnetic field produced by the winding is zero on a surface of the passive magnetic shielding material.

3. The method of claim 1 or of claim 2, wherein accounting for the presence of the passive magnetic shielding material comprises constructing a function, or discrete approximation thereof, for a geometry of the structure, that can be used to solve differential equations relating magnetic field to current density.

4. The method of claim 3, wherein the function is a Green's function subject to one or more Dirichlet boundary conditions, and further comprising implementing the method of mirror images.

5. The method of any preceding claim, wherein determining an optimised configuration of the winding comprises implementing an optimisation process.

6. The method of claim 5, wherein the optimisation process comprises a least squares minimisation process, and optionally further comprises regularising the least squares minimisation with a penalty term, and further optionally wherein the penalty term comprises at least one of a power consumption of the winding, a curvature of the winding configuration, a resistance, an inductance of the winding, a mass and/or volume of the winding, and an energy stored in the winding.

7. The method of claim 5, wherein the optimisation process comprises solving a set of simultaneous equations.

8. The method of any preceding claim, wherein determining an optimised configuration of the winding comprises determining optimal surface currents on the structure required to produce the specified magnetic field within the structure.

9. The method of claim 8, wherein the surface currents are defined by a streamfunction, and determining the optimal surface currents comprises determining streamlines of the streamfunction.

10. The method of claim 9, wherein determining streamlines of the streamfunction comprises discretising the streamfunction to determine contours of the streamfunction.

11. The method of any preceding claim, wherein determining an optimised configuration of the winding comprises:
defining at least one discrete winding element having at least one free parameter; and
optimising the at least one free parameter of each of the discrete winding elements to produce the specified magnetic field within the structure.

12. The method of claim 11, wherein optimising the at least one free parameter of the discrete winding elements comprises:
determining expressions for components of current density for each of the discrete winding elements;
substituting the expressions for components of current density into expressions for components of the magnetic field produced by an arbitrary winding configuration; and
implementing an optimisation process to determine, for the specified field, optimal values relating to the components of current density.

13. The method of claim 12, wherein the optimal values are or include an optimal relationship between free parameters of the discrete winding elements.

14. The method of any of claims 11 to 13, wherein the at least one free parameter of each discrete winding element comprises at least one of a size, a shape, a spacing, a placement and an orientation of the discrete winding element.

15. The method of any preceding claim, wherein the magnetic field is one of a constant magnetic field, a linear gradient magnetic field and a higher-order magnetic field.

16. The method of any preceding claim, wherein the structure is a closed structure.

17. The method of any preceding claim, wherein the structure is a hollow cylinder.

18. The method of claim 17 as it depends from claim 16, wherein the hollow cylinder comprises an axial body and planar end surfaces.

19. The method of claim 18, wherein separate boundary conditions are implemented for an axial surface of the cylinder and planar end surfaces of the cylinder.

20. The method of any of claims 1 to 19, further comprising manufacturing a winding corresponding to or approximating the determined optimised configuration.

21. A magnetic shield designed using the method of any of claims 1 to 20.

22. A magnetic shield comprising:
a structure enclosing a space, the structure comprising passive magnetic shielding material; and
a winding configured to produce a specified magnetic field within the structure when current is passed through the winding;
wherein a configuration of the winding is optimised such that a field produced by the winding is more similar to the specified magnetic field when the winding is in the presence of the structure than when the winding is not in the presence of the structure.

23. The magnetic shield of claim 22, wherein the structure is a closed structure.

24. The magnetic shield of claim 22 or of claim 23, wherein the structure is a hollow cylinder.

25. The magnetic shield of any of claims 22 to 24, wherein the winding is disposed within the space enclosed by the structure, and optionally wherein the winding is disposed on an interior surface of the structure.

26. The magnetic shield of any of claims 22 to 25, wherein the winding, in the presence of the structure is configured to produce a uniform magnetic field over a volume of at least 1000 cm³ with a relative field variation of less than 1%.
